(19) United States
(12) Patent Application Publication
(10) Pub. No.: US 2026/0020313 A1
(43) Pub. Date: Jan. 15, 2026

(54) SEMICONDUCTOR DEVICE

(71) Applicant: Nuvoton Technology Corporation Japan, Kyoto (JP)

(72) Inventors: Katsuhiko KAWASHIMA, Hyogo (JP); Yusuke KANDA, Toyama (JP); Kaname MOTOYOSHI, Hyogo (JP); Yoshiteru SENSHU, Toyama (JP)

(21) Appl. No.: 19/330,259

(22) Filed: Sep. 16, 2025

Related U.S. Application Data
(63) Continuation of application No. PCT/JP2024/011701, filed on Mar. 25, 2024.
(60) Provisional application No. 63/493,089, filed on Mar. 30, 2023.

(51) Int. Cl. H10D 64/27; H01L 23/31; H10D 30/01; H10D 30/47; H10D 62/10; H10D 62/824; H10D 64/00

(52) U.S. Cl. CPC H10D 64/411; H01L 23/3171; H01L 23/3192; H10D 30/015; H10D 30/475; H10D 62/116; H10D 64/111; H10D 62/824

(57) ABSTRACT

A semiconductor device includes: a substrate; a channel layer; a nitride semiconductor layer that includes a barrier layer; a source electrode; a drain electrode; a gate electrode; a drain-side insulating layer; and a source-side insulating layer. The gate electrode includes a junction portion, a drain-side protruding portion, and a source-side protruding portion. The protrusion length of the source-side protruding portion is longer than the protrusion length of the drain-side protruding portion. The bottom surface of the source-side protruding portion includes a step. The height of an end portion of the bottom surface of the source-side protruding portion is greater than the height of an end portion of the bottom surface of the drain-side protruding portion.

### CROSS REFERENCE TO RELATED APPLICATIONS

This is a continuation application of PCT International Application No. PCT/JP2024/011701 filed on Mar. 25, 2024, designating the United States of America, which is based on and claims priority of U.S. Provisional Patent Application No. 63/493,089 filed on Mar. 30, 2023. The entire disclosures of the above-identified applications, including the specifications, drawings, and claims are incorporated herein by reference in their entirety.

### FIELD

The present disclosure relates to a semiconductor device.

### BACKGROUND

In recent years, development of GaN High Electron Mobility Transistors (HEMTs) used for power amplifiers for high-frequency wireless communication has been advancing. GaN HEMTs have the following three main characteristics in terms of physical properties.

More specifically, these are: an electron carrier transport mechanism utilizing the high mobility of two-dimensional electron gas (hereinafter referred to as 2 DEG); high withstand voltage due to the wide bandgap properties of the semiconductor; and high current driving capability due to high piezoelectric effect. Due to these characteristics, GaN HEMTs are optimal devices for applications that satisfy both high-speed and high-output characteristics, and their application to high-frequency wireless base stations, high-speed charging, and the like has been advancing.

The performance required for power amplifiers in high-frequency applications can be classified into two categories: gain performance and efficiency performance. For improving gain performance, reducing gate resistance is effective. To reduce gate resistance, increasing the cross-sectional area of the gate electrode is effective.

However, when the cross-sectional area of the gate electrode is increased, the area where the 2 DEG and the gate electrode face each other increases, resulting in a trade-off relationship where gate-source parasitic capacitance Cgs and gate-drain parasitic capacitance Cgd increase.

Patent Literature (PTL) 1 and 2 disclose a structure in which, in order to reduce gate-drain parasitic capacitance Cgd, the cross-sectional area of the gate electrode on the source electrode side is increased and the cross-sectional area of the gate electrode on the drain electrode side is decreased. PTL 3 discloses a gate electrode provided with protruding regions that extend to each of the source electrode side and the drain electrode side at a height somewhat separated from the 2 DEG.

### CITATION LIST

### Patent Literature

PTL 1: Japanese Unexamined Patent Application Publication No. H3-66136

PTL 2: Japanese Unexamined Patent Application Publication No. H7-307349

PTL 3: Japanese Unexamined Patent Application Publication No. 2023-95789

### SUMMARY

### Technical Problem

However, the techniques disclosed in PTL 1 and 2 cannot reduce gate-source parasitic capacitance Cgs. Although the techniques disclosed in PTL 3 can increase the distance between the protruding regions and the 2 DEG, there is room for improvement in reducing parasitic capacitances Cgs and Cgd. As 6G communication technology becomes more widespread in the future, with its progression toward even higher frequencies, there is a need to overcome the tradeoff between gate resistance and parasitic capacitances (Cgs and Cgd) to enhance gain performance.

In view of the above, the present disclosure provides a semiconductor device capable of improving gain performance.

### Solution to Problem

A semiconductor device according to one aspect of the present disclosure includes: a substrate; a channel layer disposed above the substrate and including a nitride semiconductor containing gallium; a nitride semiconductor layer disposed above the channel layer and including a barrier layer containing gallium with a bandgap larger than a bandgap of the channel layer; a source electrode and a drain electrode disposed above the substrate and spaced apart from each other; a gate electrode disposed above the barrier layer and between the source electrode and the drain electrode, and spaced apart from each of the source electrode and the drain electrode; a drain-side insulating layer disposed above the nitride semiconductor layer and between the gate electrode and the drain electrode; and a source-side insulating layer disposed above the nitride semiconductor layer and between the gate electrode and the source electrode. The gate electrode includes: a junction portion that forms a Schottky junction with the nitride semiconductor layer; a first protruding portion that protrudes toward the drain electrode from the junction portion; and a second protruding portion that protrudes toward the source electrode from the junction portion. A protrusion length of the second protruding portion is longer than a protrusion length of the first protruding portion. A bottom surface of the second protruding portion includes a step. A height from a top surface of the nitride semiconductor layer to an end portion, of the bottom surface of the second protruding portion, that is closest to the source electrode is greater than a height from the top surface of the nitride semiconductor layer to an end portion, of a bottom surface of the first protruding portion, that is closest to the drain electrode.

### Advantageous Effects

With the semiconductor device according to the present disclosure, gain performance can be improved.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view of a semiconductor device according to Embodiment 1.

FIG. 2 is a cross-sectional view of a semiconductor device according to Embodiment 2.

FIG. 3 is a cross-sectional view of a semiconductor device according to Embodiment 3.

FIG. 4 is a cross-sectional view of a semiconductor device according to Embodiment 4.

FIG. 5 is a cross-sectional view of a semiconductor device according to Embodiment 5.

FIG. 6A is a cross-sectional view for explaining a process of a manufacturing method of the semiconductor device according to Embodiment 1.

FIG. 6B is a cross-sectional view for explaining a process of a manufacturing method of the semiconductor device according to Embodiment 1.

FIG. 6C is a cross-sectional view for explaining a process of a manufacturing method of the semiconductor device according to Embodiment 1.

FIG. 6D is a cross-sectional view for explaining a process of a manufacturing method of the semiconductor device according to Embodiment 1.

FIG. 6E is a cross-sectional view for explaining a process of a manufacturing method of the semiconductor device according to Embodiment 1.

FIG. 6F is a cross-sectional view for explaining a process of a manufacturing method of the semiconductor device according to Embodiment 1.

FIG. 6G is a cross-sectional view for explaining a process of a manufacturing method of the semiconductor device according to Embodiment 1.

FIG. 6H is a cross-sectional view for explaining a process of a manufacturing method of the semiconductor device according to Embodiment 1.

FIG. 6I is a cross-sectional view for explaining a process of a manufacturing method of the semiconductor device according to Embodiment 1.

FIG. 7A is a cross-sectional view for explaining a process of a manufacturing method of the semiconductor device according to Embodiment 5.

FIG. 7B is a cross-sectional view for explaining a process of a manufacturing method of the semiconductor device according to Embodiment 5.

FIG. 7C is a cross-sectional view for explaining a process of a manufacturing method of the semiconductor device according to Embodiment 5.

FIG. 7D is a cross-sectional view for explaining a process of a manufacturing method of the semiconductor device according to Embodiment 5.

FIG. 7E is a cross-sectional view for explaining a process of a manufacturing method of the semiconductor device according to Embodiment 5.

FIG. 7F is a cross-sectional view for explaining a process of a manufacturing method of the semiconductor device according to Embodiment 5.

FIG. 7G is a cross-sectional view for explaining a process of a manufacturing method of the semiconductor device according to Embodiment 5.

FIG. 7H is a cross-sectional view for explaining a process of a manufacturing method of the semiconductor device according to Embodiment 5.

FIG. 7I is a cross-sectional view for explaining a process of a manufacturing method of the semiconductor device according to Embodiment 5.

FIG. 7J is a cross-sectional view for explaining a process of a manufacturing method of the semiconductor device according to Embodiment 5.

FIG. 8 is a small-signal equivalent circuit diagram of a semiconductor device according to each embodiment.

FIG. 9 is a diagram for explaining gain improvement.

FIG. 10 is a cross-sectional view of a semiconductor device according to a comparative example.

FIG. 11 illustrates the drain voltage dependence of gate resistance in comparison between a comparative example and an embodiment example.

FIG. 12 illustrates the drain voltage dependence of gate-source parasitic capacitance in comparison between a comparative example and an embodiment example.

FIG. 13 illustrates the drain voltage dependence of switching frequency in comparison between a comparative example and an embodiment example.

### DESCRIPTION OF EMBODIMENTS

### Overview of Present Disclosure

Hereinafter, embodiments will be described in detail with reference to the drawings.

Each of the embodiments described below shows a general or specific example. The numerical values, shapes, materials, elements, the arrangement and connection of the elements, steps, the processing order of the steps etc., described in the following embodiments are mere examples, and therefore do not limit the scope of the present disclosure. Among elements in the embodiments described below, those not recited in the independent claims are described as optional elements.

The drawings are schematically illustrated diagrams and do not necessarily give strict illustration. Therefore, for example, the scale and the like in the drawing do not necessarily match. Throughout the drawings, the same reference signs are given to elements that are substantially the same, and redundant description will be omitted or simplified.

In the present specification, terms indicating relationships between elements, such as parallel or perpendicular, terms indicating the shapes of elements, such as quadrilateral, and value ranges do not have the meanings in the strict sense only, but also represent essentially equivalent meanings and value ranges, and include, for example, deviations of about a few percent.

In the present specification, the terms “above” and “below” do not refer to the vertically upward direction and vertically downward direction in terms of absolute spatial recognition, but are used as terms defined by relative positional relationships based on the stacking order in a stacked configuration. In addition, the terms “above” and “below” are used not only when an element is present between two other elements spaced apart from each other, but also when two elements are disposed in close contact with each other.

In the present specification and drawings, the x-axis, the y-axis, and the z-axis refer to the three axes of a three-dimensional orthogonal coordinate system. Specifically, the x-axis and the y-axis are the two axes parallel to the main surface (top surface) included in a substrate that the semiconductor device includes, and the direction perpendicular to this main surface is a z-axis direction. More specifically, the direction in which the source electrode, the gate electrode, and the drain electrode are aligned in stated order; that is, the so-called gate length direction is referred to as the x-axis direction. In the embodiments described below, there are instances where the z-axis positive direction is described as “above” and the z-axis negative direction is described as “below”. In the present specification, unless otherwise specified, the source electrode side or the source side each means the negative side (negative direction) of the x-axis, and the drain electrode side or the drain side each means the positive side (positive direction) of the x-axis. In addition, in the present specification, “plan view” refers to the view of the main surface (top surface) of the substrate included in the semiconductor device from the z-axis positive direction, unless otherwise specified.

In addition, in the present specification, a group III nitride semiconductor is a semiconductor that contains one or more types of group III elements and nitrogen. Group III elements are, for example, aluminum (Al), gallium (Ga), indium (In), etc. GaN, AlN, InN, AlGaN, InGaN, and AlInGaN are included as examples of the group III nitride semiconductor. Group III nitride semiconductors may contain one or more types of elements other than Group III, such as silicon (Si) and phosphorus (P). It should be noted that, in the following description, when described as AlInGaN without any particular explanation, it means that the group III nitride semiconductor contains each of Al, In, Ga, and N. The same applies to other descriptions such as AlGaN and GaN.

A layer consisting of material A such as a group III nitride semiconductor like GaN or AlGaN, silicon nitride, or silicon oxide, and a layer composed of material A each mean that the layer contains substantially only material A. However, the above-described layer may contain other elements, as impurities, such as elements that cannot be avoided in the manufacturing process, at a ratio of 1at % or less.

In addition, in the present specification, the composition ratio of the group III element of a nitride semiconductor (layer) represents the ratio of a total number of atoms of the target group III element among a plurality of group III elements included in the nitride semiconductor. For example, when a nitride semiconductor layer consists of AlₐIn_{b}Ga_{c}N (a+b+c=1, a≥0, b≥0, c≥0), the Al composition ratio of the nitride semiconductor layer can be expressed as a/(a+b+c). In the same manner, the In composition ratio and the Ga composition ratio are expressed as b/(a+b+c) and c/(a+b+c), respectively.

In addition, in the present specification, ordinal numerals such as “first” and “second” do not mean a total number or an order of elements, unless otherwise noted, but are used to avoid confusion and distinguish between elements of the same type.

### Embodiment 1

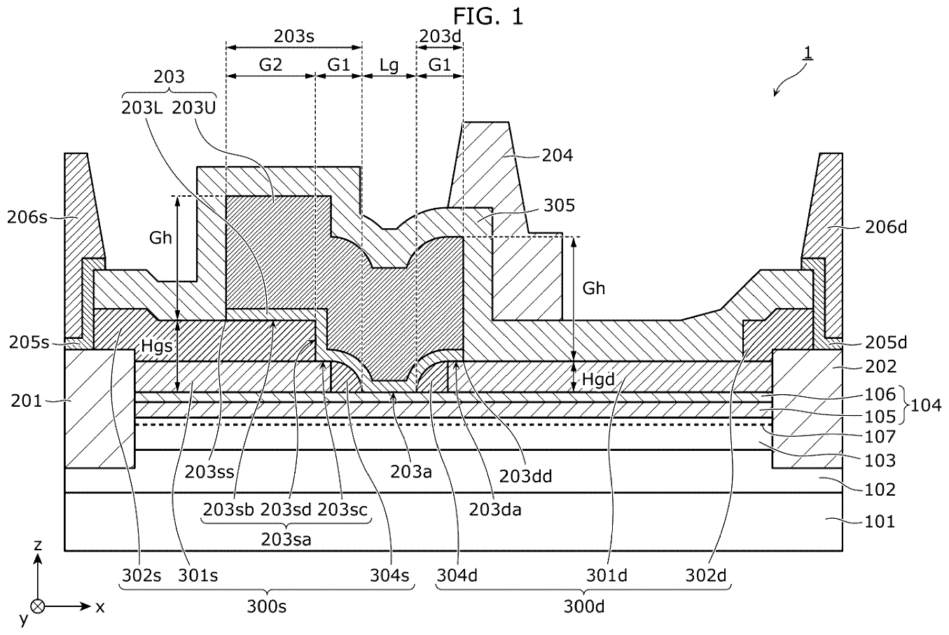

First, a semiconductor device according to Embodiment 1 will be described with reference to FIG. 1. FIG. 1 is a cross-sectional view of semiconductor device 1 according to the present embodiment.

As illustrated in FIG. 1, semiconductor device 1 includes substrate 101, buffer layer 102, channel layer 103, and nitride semiconductor layer 104. Nitride semiconductor layer 104 includes barrier layer 105 and cap layer 106. 2 DEG 107 is formed in proximity to the interface between channel layer 103 and barrier layer 105. Buffer layer 102, channel layer 103, barrier layer 105 and cap layer 106 are epitaxial layers (also called epi layers) formed by epitaxial growth. Semiconductor device 1 includes source electrode 201, drain electrode 202, gate electrode 203, source field plate 204, barrier metals 205s and 205d, and wiring metals 206s and 206d. Semiconductor device 1 includes drain-side insulating layer 300d, source-side insulating layer 300s, and insulating layer 305. Source-side insulating layer 300s includes first insulating film 301s, second insulating film 302s, and sidewall 304s. Drain-side insulating layer 300d includes third insulating film 301d, fourth insulating film 302d, and sidewall 304d.

Substrate 101 is a substrate consisting of Si. Alternatively, substrate 101 may be a Silicon on Insulator (SOI) substrate. Substrate 101 may also be a substrate consisting of SiC, sapphire, diamond, GaN, or AlN, or the like.

Buffer layer 102 is disposed above substrate 101. For example, buffer layer 102 is disposed in contact with the top surface of substrate 101. Buffer layer 102 is, for example, a layer consisting of a group III nitride semiconductor. As an example, buffer layer 102 has a stacked structure consisting of a plurality of layers of AlN and AlGaN, and has a thickness of 2 μm. Buffer layer 102 may otherwise be composed of a single layer or a plurality of layers of group III nitride semiconductors such as GaN, AlGaN, AlN, InGaN, AlInGaN, etc.

Providing buffer layer 102 makes it possible to reduce adverse effects such as crystal dislocation and lattice defects resulting from the difference in lattice spacing between substrate 101 and channel layer 103. Even if there are defects in substrate 101, providing buffer layer 102 makes it possible to inhibit the influence these defects have on channel layer 103. With this configuration, it is possible to reduce defects in channel layer 103, enhance crystallinity, and increase electron mobility in channel layer 103. Note that buffer layer 102 need not necessarily be provided.

Channel layer 103 is disposed above substrate 101. Specifically, channel layer 103 is disposed in contact with the top surface of buffer layer 102. Channel layer 103 is a layer consisting of a nitride semiconductor containing gallium. For example, channel layer 103 is composed of GaN. The thickness of channel layer 103 is, for example, greater than or equal to 50 nm and less than or equal to 300 nm, and in one example is 200 nm. It should be noted that channel layer 103 is not limited to GaN, but may be composed of a group III nitride semiconductor such as InGaN, AlGaN, AlInGaN, etc. In addition, channel layer 103 may contain an n-type impurity. The thickness of channel layer 103 is not limited to the example described above.

Barrier layer 105 is disposed above channel layer 103. Specifically, barrier layer 105 is disposed in contact with the top surface of channel layer 103. Note that a spacer layer consisting of AlN with a thickness of approximately 1 nm may be disposed between barrier layer 105 and channel layer 103. As described above, channel layer 103 and barrier layer 105 need not necessarily be in contact with each other.

Barrier layer 105 is a layer consisting of a nitride semiconductor containing gallium with a larger bandgap than channel layer 103. Barrier layer 105 is composed of, for example, AlGaN. The Al composition ratio of barrier layer 105 is, for example, greater than or equal to 10% and less than or equal to 30%, but may be greater than or equal to 20% and less than or equal to 30%. The Al composition ratio of barrier layer 105 is, in one example, less than or equal to 25%. The thickness of barrier layer 105 is greater than or equal to 7 nm and less than or equal to 10 nm, and in one example is 9 nm. Note that the thickness of barrier layer 105 may be less than or equal to 15 nm, may be less than or equal to 20 nm, and may be less than or equal to 30 nm. In addition, barrier layer 105 is not limited to AlGaN, but may be composed of a group III nitride semiconductor such as AlInGaN, etc. In addition, barrier layer 105 may contain an n-type impurity.

By barrier layer 105 containing gallium, the lattice spacing of barrier layer 105 is more easily relaxed compared to when it is composed of AlN that does not contain gallium. For this reason, it is possible to inhibit the occurrence of cracks, etc., in barrier layer 105. It is also possible to inhibit bowing of the wafer. Therefore, the quality of semiconductor device 1 can be improved.

A high-concentration 2 DEG 107 is generated on the channel layer 103 side of the hetero interface between barrier layer 105 and channel layer 103 due to piezo stress, etc., of barrier layer 105 with respect to channel layer 103. 2 DEG 107 is used as a channel for the transistor.

Cap layer 106 contacts and covers the top surface of barrier layer 105. Cap layer 106 is a layer consisting of a group III nitride semiconductor. Cap layer 106 is composed of, for example, GaN. The thickness of cap layer 106 is, for example, greater than or equal to approximately 1 nm and less than or equal to approximately 2 nm. Providing cap layer 106 makes it possible to inhibit oxidation of Al in barrier layer 105. Cap layer 106 need not necessarily be provided.

Source electrode 201 and drain electrode 202 are disposed apart from each other, above substrate 101. More specifically, source electrode 201 and drain electrode 202 are disposed facing each other with gate electrode 203 interposed therebetween.

Source electrode 201 and drain electrode 202 are formed using conductive materials. For example, source electrode 201 and drain electrode 202 are multilayer electrode films having a stacked structure in which a Ti film and an Al film are stacked in sequence, but not limited to this example. Source electrode 201 and drain electrode 202 may be an alloy layer formed by annealing the stacked structure of a Ti film and an Al film at a temperature of 500° C. or higher. Source electrode 201 and drain electrode 202 may be a transition metal, or a nitride or carbide of a transition metal. More specifically, source electrode 201 and drain electrode 202 may be Ta, Hf, W, Ni, TiN, TaN, HfN, WN, TiC, TaC, HfC, Au, Cu, etc., a compound containing these elements, or a multilayer electrode film having a plurality of stacked structures.

Source electrode 201 and drain electrode 202 are each also called ohmic electrodes, and are each electrically in ohmic contact with 2 DEG 107. In the present embodiment, source electrode 201 and drain electrode 202 are each disposed so as to be in contact with 2 DEG 107.

More specifically, in semiconductor device 1, two recesses are provided that penetrate through cap layer 106 and barrier layer 105 to reach channel layer 103. The two recesses are also referred to as a source opening portion and a drain opening portion. Source electrode 201 is disposed so as to be in contact with and cover the inner surface of the source opening portion, and drain electrode 202 is disposed so as to be in contact with and cover the inner surface of the drain opening portion. The bottom surface of each of the two recesses is located below the interface between channel layer 103 and barrier layer 105. Accordingly, 2 DEG 107 is exposed on the side surface of each of the two recesses. Source electrode 201 and drain electrode 202 are in contact with 2 DEG 107 on the side surfaces of the recesses. This configuration makes it possible to reduce the channel contact resistance. Note that instead of the recesses, a source contact region and a drain contact region with reduced resistance may be provided by adding n-type impurities to portions of cap layer 106, barrier layer 105, and channel layer 103. The source contact region and the drain contact region are formed by, for example, plasma treatment, ion implantation, and crystal regrowth.

Source electrode 201 and drain electrode 202 are each covered with an insulating film (specifically, insulating layer 305 before openings are formed) during the manufacturing process of semiconductor device 1. In order to ensure contact to source electrode 201 and drain electrode 202, openings are provided in insulating layer 305, and wiring metals 206s and 206d are connected to source electrode 201 and drain electrode 202, respectively, through the openings. Wiring metals 206s and 206d are formed using, for example, low-resistance Au.

When wiring metal 206s containing Au comes into contact with source electrode 201 containing Al, a reaction between the materials may occur under high-temperature environments. To avoid this reaction, barrier metal 205s is disposed between source electrode 201 and wiring metal 206s. Similarly, barrier metal 205d is disposed between drain electrode 202 and wiring metal 206d. Barrier metals 205d and 205s are formed using a material containing a metal with a high melting point that is unlikely to react even at high temperatures. For example, barrier metals 205d and 205s are TiN films. It should be noted that barrier metals 205d and 205s, as well as wiring metals 206d and 206s, need not necessarily be provided. For example, source electrode 201 and drain electrode 202 may additionally serve as wiring.

Gate electrode 203 is disposed above barrier layer 105, between source electrode 201 and drain electrode 202 so as to be spaced apart from each of source electrode 201 and drain electrode 202. In the present embodiment, gate electrode 203 has a multilayer structure including gate electrode lower portion 203L and gate electrode upper portion 203U.

Gate electrode lower portion 203L is formed using a conductive material that can form a Schottky junction with a nitride semiconductor containing gallium. For example, gate electrode lower portion 203L is formed using Ni, Ti, TiN, TaN, W, Pd, or the like. Gate electrode lower portion 203L is positioned as the lowermost layer of the multilayer structure of gate electrode 203, and is in contact with cap layer 106, drain-side insulating layer 300d, and source-side insulating layer 300s. The thickness of gate electrode lower portion 203L is, for example, greater than or equal to 25 nm and less than or equal to 100 nm, and in one example is 50 nm, but is not limited thereto.

Gate electrode upper portion 203U is formed using a material having a lower resistivity than gate electrode lower portion 203L. For example, gate electrode upper portion 203U is formed using Au or Al, or the like. Gate electrode upper portion 203U is disposed so as to be in contact with and cover the top surface of gate electrode lower portion 203L. The thickness of gate electrode upper portion 203U is, for example, greater than or equal to 450 nm and less than or equal to 650 nm, and in one example is 500 nm, but is not limited thereto. In plan view, the shape and size of gate electrode upper portion 203U are substantially the same as the shape and size of gate electrode lower portion 203L.

Giving gate electrode 203 a multilayer structure in this manner makes it possible to reduce gate resistance Rg in the y-axis direction while ensuring the Schottky junction. Reducing gate resistance Rg makes it possible to improve high-frequency gain. Note that gate electrode 203 need not have a multilayer structure, and may have a single-layer structure formed using a conductive material that can form a Schottky junction with a nitride semiconductor containing gallium.

Gate electrode 203 has a so-called T-type gate structure. More specifically, gate electrode 203 includes junction portion 203a, drain-side protruding portion 203d, and source-side protruding portion 203s. Drain-side protruding portion 203d and source-side protruding portion 203s are also referred to as gate field plates.

Junction portion 203a forms a Schottky junction with nitride semiconductor layer 104. More specifically, junction portion 203a is the portion of the bottom surface of gate electrode lower portion 203L that is in contact with cap layer 106. Note that in configurations in which cap layer 106 is not provided, junction portion 203a is the portion of the bottom surface of gate electrode lower portion 203L that is in contact with barrier layer 105.

Drain-side protruding portion 203d is one example of the first protruding portion, and is a portion that protrudes toward the drain electrode 202 side from junction portion 203a. Drain-side protruding portion 203d corresponds to one arm of the T-shape in the T-type gate structure.

Source-side protruding portion 203s is one example of the second protruding portion, and is a portion that protrudes toward the source electrode 201 side from junction portion 203a. Source-side protruding portion 203s corresponds to one arm of the T-shape in the T-type gate structure.

In semiconductor device 1 according to the present embodiment, gate electrode 203 has a characteristic cross-sectional shape. The specific content of this will be explained later.

Source field plate 204 is disposed above gate electrode 203 and set at the same electric potential as source electrode 201. More specifically, source field plate 204 is disposed above insulating layer 305. Source field plate 204 is disposed such that at least a portion thereof is positioned between gate electrode 203 and drain electrode 202 in a plan view. In the example illustrated in FIG. 1, source field plate 204 is placed such that a portion thereof overlaps gate electrode 203 in a plan view. Source field plate 204 is electrically insulated from gate electrode 203 and drain electrode 202, and is set at an electric potential (source electric potential) applied to source electrode 201.

During operation of semiconductor device 1, a high voltage of approximately 100 V to 150 V maximum is applied to drain electrode 202. At that time, a high electric field is applied between drain electrode 202 and gate electrode 203. More specifically, electric power lines from drain electrode 202 concentrate at the end portion of drain-side protruding portion 203d of gate electrode 203, causing the peak value of the electric field to increase and reliability to decrease. Providing source field plate 204 makes it possible to reduce the peak value of this electric field. Source field plate 204 can relax the high electric field peak by dispersing it in the x-axis direction. With this configuration, it is possible to improve the withstand voltage between the gate and drain, and improve the reliability by inhibiting the gate leakage current.

Source field plate 204 is formed using a conductive material. Source field plate 204 is, for example, a multilayer electrode film having a stacked structure in which a TiN film and an Al film are stacked in sequence. The thickness of source field plate 204 is, for example, 500 nm, but is not limited thereto. It should be noted that source field plate 204 is not limited to the stacked structure of a TIN film and an Al film, but may be a nitride or carbide of a transition metal deposited by sputtering. More specifically, source field plate 204 may be Ti, Ta, W, Ni, TiN, TaN, WN, W, Au, Cu, etc., a compound containing these elements, or a multilayer electrode film having a plurality of stacked structures. In one example, source field plate 204 has a multilayer structure in which Ti, TIN, and Al are stacked in this order from the bottom layer. Alternatively, source field plate 204 may include Au in the uppermost layer.

Insulating layer 305 is disposed between gate electrode 203 and source field plate 204. More specifically, insulating layer 305 is disposed so as to cover the entire area of semiconductor device 1. Insulating layer 305 includes openings for securing contact to each of source electrode 201 and drain electrode 202.

Insulating layer 305 is composed of Si₃N₄ with a thickness of 110 nm, for example. It should be noted that insulating layer 305 is not limited to Si₃N₄, but may be SiO₂ or SiON. Si₃N₄ included in insulating layer 305 may be stress controlled by changing the Si composition ratio or the N composition ratio. It should be noted that insulating layer 305 and source field plate 204 need not necessarily be provided.

Drain-side insulating layer 300d is disposed above nitride semiconductor layer 104 and disposed between gate electrode 203 and drain electrode 202. Drain-side insulating layer 300d overlaps with drain-side protruding portion 203d in a plan view. More specifically, drain-side insulating layer 300d is disposed between gate electrode 203 and drain electrode 202, contacting and covering the top surface of cap layer 106. Drain-side insulating layer 300d is disposed over the entire area from the drain-side end portion of junction portion 203a to drain electrode 202.

Drain-side insulating layer 300d includes third insulating film 301d, fourth insulating film 302d, and sidewall 304d. It should be noted that fourth insulating film 302d and sidewall 304d need not necessarily be provided.

Third insulating film 301d is positioned between drain-side protruding portion 203d of gate electrode 203 and nitride semiconductor layer 104. More specifically, third insulating film 301d overlaps with drain-side protruding portion 203d in a plan view, and contacts bottom surface 203da of drain-side protruding portion 203d. Third insulating film 301d contacts and covers nitride semiconductor layer 104 in the area from the position overlapping with drain-side protruding portion 203d in a plan view of substrate 101 to drain electrode 202. Third insulating film 301d consists of silicon nitride (Si₃N₄), for example.

Fourth insulating film 302d is disposed above third insulating film 301d. Fourth insulating film 302d does not overlap with drain-side protruding portion 203d in a plan view of substrate 101. For example, fourth insulating film 302d is in contact with drain electrode 202. Fourth insulating film 302d overlaps with drain electrode 202 in a plan view and is provided so as to extend toward the gate electrode 203 side. Fourth insulating film 302d consists of Si₃N₄, for example, but may consist of silicon oxide (SiO₂) or silicon oxynitride (SiON).

Sidewall 304d is disposed between junction portion 203a of gate electrode 203 and third insulating film 301d. Sidewall 304d consists of Si₃N₄, for example. Sidewall 304d is formed in the same process as fourth insulating film 302d. Providing sidewall 304d makes it possible to shorten gate length Lg.

Source-side insulating layer 300s is disposed above nitride semiconductor layer 104 and disposed between gate electrode 203 and source electrode 201. Source-side insulating layer 300s overlaps with source-side protruding portion 203s in a plan view. More specifically, source-side insulating layer 300s contacts and covers the top surface of cap layer 106, between gate electrode 203 and source electrode 201. Source-side insulating layer 300s is disposed over the entire area from the source-side end portion of junction portion 203a to source electrode 201.

Source-side insulating layer 300s includes first insulating film 301s, second insulating film 302s, and sidewall 304s. Note that sidewall 304s need not necessarily be provided.

First insulating film 301s is positioned between source-side protruding portion 203s of gate electrode 203 and nitride semiconductor layer 104. More specifically, first insulating film 301s overlaps with source-side protruding portion 203s in a plan view, and contacts bottom surface 203sa of source-side protruding portion 203s. First insulating film 301s contacts and covers nitride semiconductor layer 104 in the area from the position overlapping with source-side protruding portion 203s in a plan view of substrate 101 to source electrode 201. First insulating film 301s consists of Si₃N₄, for example.

First insulating film 301s can be formed in the same process as third insulating film 301d on the drain electrode 202 side. Therefore, first insulating film 301s has the same thickness and film quality as third insulating film 301d. For example, the thickness of each of first insulating film 301s and third insulating film 301d is greater than or equal to 50 nm and less than or equal to 150 nm, and in one example is 100 nm, but is not limited thereto.

Second insulating film 302s is positioned between source-side protruding portion 203s and first insulating film 301s. More specifically, second insulating film 302s overlaps with source-side protruding portion 203s in a plan view, and contacts bottom surface 203sa of source-side protruding portion 203s. Second insulating film 302s contacts and covers first insulating film 301s in the area from the position overlapping with source-side protruding portion 203s in a plan view of substrate 101 to source electrode 201. Second insulating film 302s consists of Si₃N₄, for example, but may consist of SiO₂ or SiON. For example, when second insulating film 302s includes a SiO₂ film, SiO₂ has a lower dielectric constant than Si₃N₄. Therefore, gate-source parasitic capacitance Cgs can be further reduced.

The end portion of second insulating film 302s proximate to drain electrode 202, i.e., on the drain electrode 202 side (positive side of the x-axis) is receded toward the source electrode 201 side (negative side of the x-axis) relative to the end portion of first insulating film 301s proximate to drain electrode 202, i.e., on the drain electrode 202 side. Therefore, a portion of the top surface of first insulating film 301s is not covered by second insulating film 302s, and contacts bottom surface 203sa of source-side protruding portion 203s of gate electrode 203. A step is formed on bottom surface 203sa of source-side protruding portion 203s of gate electrode 203 due to the receded end portion of second insulating film 302s.

Second insulating film 302s can be formed in the same process as fourth insulating film 302d on the drain electrode 202 side. Therefore, second insulating film 302s has the same thickness and film quality as fourth insulating film 302d. For example, the thickness of each of second insulating film 302s and fourth insulating film 302d is greater than or equal to 50 nm and less than or equal to 150 nm, and in one example is 100 nm, but is not limited thereto.

Sidewall 304s is disposed between junction portion 203a of gate electrode 203 and first insulating film 301s. Sidewall 304s consists of Si₃N₄, for example. Sidewall 304s is formed in the same process as second insulating film 302s. Providing sidewall 304s makes it possible to shorten gate length Lg.

Next, a characteristic cross-sectional configuration of gate electrode 203 in semiconductor device 1 according to the present embodiment will be described in detail.

In the present embodiment, gate electrode 203 has a cross-sectional shape that is asymmetrical in the xz cross-section. More specifically, the protrusion length of source-side protruding portion 203s is longer than the protrusion length of drain-side protruding portion 203d. For example, as illustrated in FIG. 1, the protrusion length of drain-side protruding portion 203d is G1. In contrast, the protrusion length of source-side protruding portion 203s is G1+G2. For example, G1 is greater than or equal to 0.10 μm and less than or equal to 0.25 μm, and in one example is 0.15 μm. G2 is greater than or equal to 0.30 μm and less than or equal to 0.50 μm, and in one example is 0.45 μm.

It should be noted that the protrusion length of the protruding portion refers to the distance along the x-axis direction from the starting point to the tip of the protruding portion. The starting point of the protruding portion can be considered as the outline of junction portion 203a in plan view. The tip of the protruding portion is the position farthest from the starting point in the protrusion direction of the protruding portion. For drain-side protruding portion 203d, the protrusion direction is the positive direction of the x-axis, and for source-side protruding portion 203s, the protrusion direction is the negative direction of the x-axis.

By providing drain-side protruding portion 203d and source-side protruding portion 203s, it is possible to increase the cross-sectional area of gate electrode 203 while shortening gate length Lg. Therefore, gate resistance Rg can be reduced, making it possible to improve gain performance for high frequencies. By making the protrusion length of drain-side protruding portion 203d shorter than the protrusion length of source-side protruding portion 203s, the opposing area between gate electrode 203 and 2 DEG 107 connected to drain electrode 202 becomes smaller. Therefore, gate-drain parasitic capacitance Cgd can be reduced.

However, since the protrusion length of source-side protruding portion 203s is longer than the protrusion length of drain-side protruding portion 203d, the opposing area between gate electrode 203 and 2 DEG 107 connected to source electrode 201 becomes larger. Therefore, gate-source parasitic capacitance Cgs can become large. In contrast, in the present embodiment, bottom surface 203sa of source-side protruding portion 203s of gate electrode 203 includes a step. No step is provided on bottom surface 203da of drain-side protruding portion 203d.

More specifically, as illustrated in FIG. 1, bottom surface 203sa of source-side protruding portion 203s includes upper portion 203sb, lower portion 203sc, and sidewall portion 203sd. Upper portion 203sb is the portion of bottom surface 203sa of source-side protruding portion 203s that is in contact with the top surface of second insulating film 302s. Lower portion 203sc is the portion of bottom surface 203sa that is in contact with the top surface of first insulating film 301s. Sidewall portion 203sd is a portion that connects upper portion 203sb and lower portion 203sc, and is in contact with the side surface of second insulating film 302s.

Sidewall portion 203sd is, for example, perpendicular to the main surface (xy plane) of substrate 101. Alternatively, sidewall portion 203sd may be an inclined surface that is inclined with respect to substrate 101. The inclination angle of sidewall portion 203sd (the angle with respect to xy plane) is, for example, greater than or equal to 45 degrees. By providing sidewall portion 203sd, upper portion 203sb and lower portion 203sc become discontinuous. That is, a step is provided on bottom surface 203sa of source-side protruding portion 203s.

By including a step, bottom surface 203sa of source-side protruding portion 203s has an increased distance from nitride semiconductor layer 104 (and 2 DEG 107). More specifically, as illustrated in FIG. 1, height Hgs of end portion 203ss, which is the portion of bottom surface 203sa of source-side protruding portion 203s closest to source electrode 201, from the top surface of nitride semiconductor layer 104 is greater than height Hgd of end portion 203dd, which is the portion of bottom surface 203da of drain-side protruding portion 203d closest to drain electrode 202, from the top surface of nitride semiconductor layer 104. That is, Hgs>Hgd is satisfied. Hgs corresponds to the total thickness of first insulating film 301s and second insulating film 302s. Hgd corresponds to the thickness of third insulating film 301d.

With this configuration, the distance between source-side protruding portion 203s and 2 DEG 107 can be increased, thereby making it possible to reduce gate-source parasitic capacitance Cgs. That is, it is possible to inhibit an increase in parasitic capacitance Cgs accompanying an increase in the opposing area between source-side protruding portion 203s and 2 DEG 107. Therefore, according to the present embodiment, it is possible to achieve both a reduction in gate resistance Rg and a reduction in parasitic capacitances Cgs and Cgd.

In the present embodiment, in gate electrode 203, the thickness of drain-side protruding portion 203d and the thickness of source-side protruding portion 203s are constant and equal to each other. More specifically, the thickness of gate electrode 203 is constant regardless of location. The thickness of gate electrode 203 is the distance between the bottom surface and the top surface of gate electrode 203 in the z-axis direction. Since the thickness of gate electrode 203 is constant, the cross-sectional shapes of the bottom surface and the top surface of gate electrode 203 are the same. Since the thickness of gate electrode 203 is constant, the cross-sectional area of gate electrode 203 becomes large, making it possible to reduce gate resistance Rg. Therefore, the high-frequency gain performance of semiconductor device 1 can be improved. Thickness Gh of gate electrode 203 is, for example, greater than or equal to 500 nm and less than or equal to 700 nm, but is not limited thereto.

Note that normally, when gate electrode 203 is formed, over-etching tends to occur particularly at both end portions, causing the cross-sectional shape to collapse slightly. As a result, at both end portions of gate electrode 203, cases can occur where the thickness becomes thin. For this reason, in the present specification, thickness being “constant” means that the thickness can be regarded as substantially constant, and does not mean only that the thickness values at all points are exactly identical. For example, the thickness of gate electrode 203 is considered constant when the difference between the maximum and minimum values measured at a plurality of positions does not exceed 10% of the average of measurement values.

Drain-side protruding portion 203d and source-side protruding portion 203s are each exemplified as, but not limited to, having a multilayer structure of gate electrode upper portion 203U and gate electrode lower portion 203L. For example, drain-side protruding portion 203d and source-side protruding portion 203s may each include only low-resistance gate electrode upper portion 203U. That is, gate electrode lower portion 203L may be provided only in the portion where gate electrode 203 and cap layer 106 (or barrier layer 105) are in contact with each other (i.e., the portion corresponding to junction portion 203a).

The distance along the x-axis from the drain-side end portion of junction portion 203a to drain electrode 202 is called gate-drain distance Lgd. The distance along the x-axis from the source-side end portion of junction portion 203a to source electrode 201 is called gate-source distance Lgs. In the present embodiment, Lgs<Lgd. For example, Lgd is 3.2 μm, and Lgs is 1.3 μm. By making gate-drain distance Lgd longer than gate-source distance Lgs, it is possible to relax the electric field concentration applied between the gate and drain. Note that satisfying Lgs<Lgd is not essential; Lgs may be equal to Lgd, or Lgs may be greater than Lgd.

### Embodiment 2

Next, Embodiment 2 will be described. In Embodiment 2, the main difference from Embodiment 1 is that the source-side first insulating film and the drain-side third insulating film each have a stacked structure. The description below will focus on the differences from Embodiment 1, and the description of common points will be omitted or simplified.

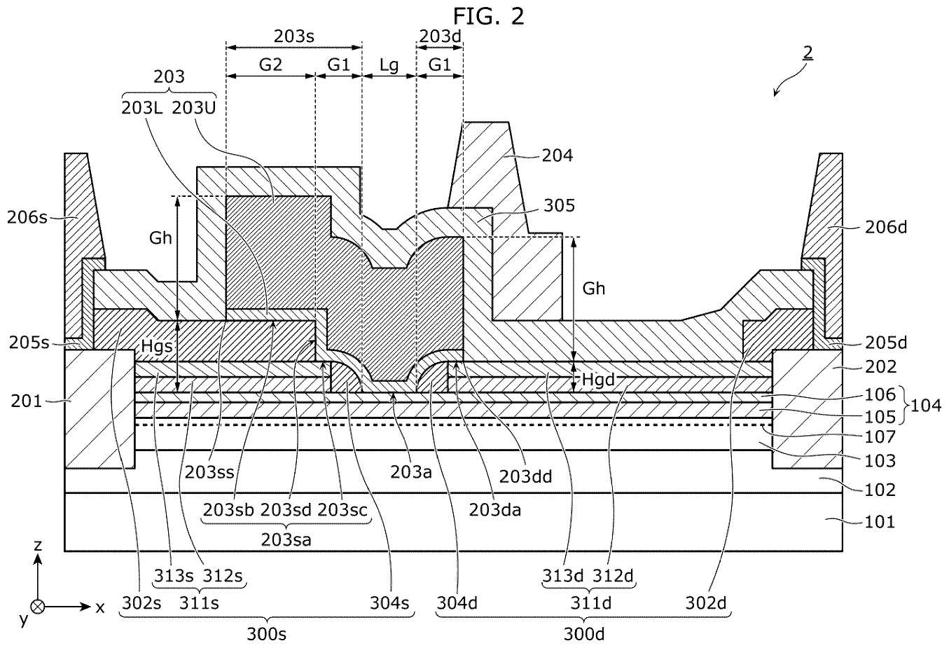

FIG. 2 is a cross-sectional view of semiconductor device 2 according to the present embodiment. As illustrated in FIG. 2, semiconductor device 2 differs from semiconductor device 1 illustrated in FIG. 1 in that source-side insulating layer 300s includes first insulating film 311s instead of first insulating film 301s, and drain-side insulating layer 300d includes third insulating film 311d instead of third insulating film 301d. First insulating film 311s and third insulating film 311d each have a stacked structure.

Specifically, first insulating film 311s includes Si₃N₄ film 312s and SiO₂ film 313s. Third insulating film 311d includes Si₃N₄ film 312d and SiO₂ film 313d.

Si₃N₄ film 312s contacts and covers nitride semiconductor layer 104. In the present embodiment, Si₃N₄ film 312s contacts and covers nitride semiconductor layer 104 in the area from the position overlapping with source-side protruding portion 203s in a plan view of substrate 101 to source electrode 201.

SiO₂ film 313s is disposed above Si₃N₄ film 312s. In the present embodiment, SiO₂ film 313s covers the entire top surface of Si₃N₄ film 312s. Therefore, the top surface of Si₃N₄ film 312s does not contact bottom surface 203sa of source-side protruding portion 203s of gate electrode 203. The top surface of SiO₂ film 313s is in contact with lower portion 203sc of bottom surface 203sa.

Si₃N₄ film 312d contacts and covers nitride semiconductor layer 104. In the present embodiment, Si₃N₄ film 312d contacts and covers nitride semiconductor layer 104 in the area from the position overlapping with drain-side protruding portion 203d in a plan view of substrate 101 to drain electrode 202.

Si₃N₄ film 312d can be formed in the same process as Si₃N₄ film 312s. Therefore, Si₃N₄ film 312d has the same thickness and film quality as Si₃N₄ film 312s. For example, the thickness of each of Si₃N₄ films 312d and 312s is greater than or equal to 10 nm and less than or equal to 100 nm, and in one example is 50 nm. In the present embodiment, the thickness of Si₃N₄ films 312d and 312s is substantially uniform.

SiO₂ film 313d is disposed above Si₃N₄ film 312d. In the present embodiment, SiO₂ film 313d covers the entire top surface of Si₃N₄ film 312d. Therefore, the top surface of Si₃N₄ film 312d does not contact bottom surface 203da of drain-side protruding portion 203d of gate electrode 203. The top surface of SiO₂ film 313d is in contact with bottom surface 203da.

SiO₂ film 313d can be formed in the same process as SiO₂ film 313s. Therefore, SiO₂ film 313d has the same thickness and film quality as SiO₂ film 313s. For example, the thickness of each of SiO₂ films 313d and 313s is, for example, greater than or equal to 10 nm and less than or equal to 100 nm, and in one example is 50 nm. In the present embodiment, the thickness of SiO₂ films 313d and 313s is substantially uniform.

While the relative dielectric constant of Si₃N₄ is approximately 7, the relative dielectric constant of SiO₂ is approximately 4. That is, SiO₂ films 313d and 313s have a lower dielectric constant than either Si₃N₄ film 312d or 312s. Therefore, by providing SiO₂ film 313d between drain-side protruding portion 203d and 2 DEG 107, gate-drain parasitic capacitance Cgd can be reduced. By providing SiO₂ film 313s between source-side protruding portion 203s and 2 DEG 107, gate-source parasitic capacitance Cgs can be reduced. By reducing gate-drain parasitic capacitance Cgd, it is possible to improve high-frequency gain performance and efficiency performance of the transistor.

It should be noted that in the present embodiment, one of first insulating film 311s on the source electrode 201 side or third insulating film 311d on the drain electrode 202 side may have a single-layer structure of Si₃N₄, similar to Embodiment 1. SiO₂ film 313d may be provided only at positions that overlap with drain-side protruding portion 203d in plan view, and need not be provided at positions that do not overlap with drain-side protruding portion 203d. Similarly, SiO₂ film 313s may be provided only at positions that overlap with source-side protruding portion 203s in plan view, and need not be provided at positions that do not overlap with source-side protruding portion 203s.

### Embodiment 3

Next, Embodiment 3 will be described. In Embodiment 3, the main difference from Embodiment 1 is that the fourth insulating film extends toward the gate electrode side. The description below will focus on the differences from Embodiment 1, and the description of common points will be omitted or simplified.

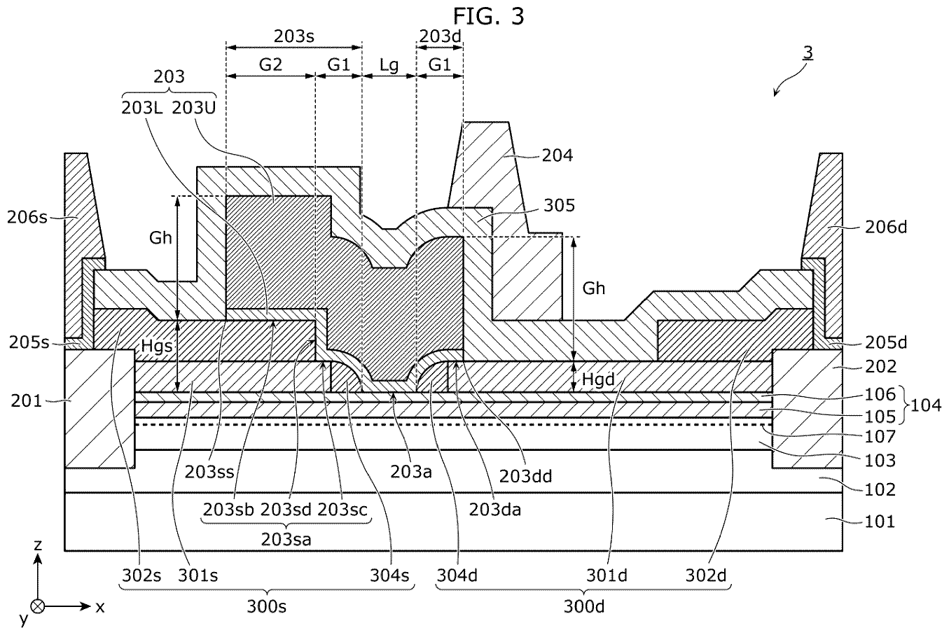

FIG. 3 is a cross-sectional view of semiconductor device 3 according to the present embodiment. As illustrated in FIG. 3, semiconductor device 3 differs from semiconductor device 1 in that fourth insulating film 302d extends toward the gate electrode 203 side.

For example, the distance in the x-axis direction between the end portion of fourth insulating film 302d on the gate electrode 203 side and the end portion of drain-side protruding portion 203d of gate electrode 203 is, for example, greater than or equal to ¼ and less than or equal to ¾ of gate-drain distance Lgd, and in one example is ½. For example, when gate-drain distance Lgd is 3 μm, the distance in the x-axis direction between the end portion of fourth insulating film 302d on the gate electrode 203 side and the end portion of drain-side protruding portion 203d of gate electrode 203 is 1.5 μm.

In the region directly below fourth insulating film 302d, the carrier concentration of 2 DEG 107 can be increased due to the effect of increased piezo stress. Therefore, the electrical resistance of 2 DEG 107 in the x-axis direction decreases. Since fourth insulating film 302d extends toward the gate electrode 203 side, the region where the electrical resistance of 2 DEG 107 decreases increases, making it possible to reduce on-resistance Ron of the transistor. Semiconductor device 3 is useful when the operating voltage is low.

### Embodiment 4

Next, Embodiment 4 will be described. In Embodiment 4, the main difference from Embodiment 2 is that the number of steps in the step structure on the bottom surface of the source-side protruding portion of the gate electrode is increased. The description below will focus on the differences from Embodiment 2, and the description of common points will be omitted or simplified.

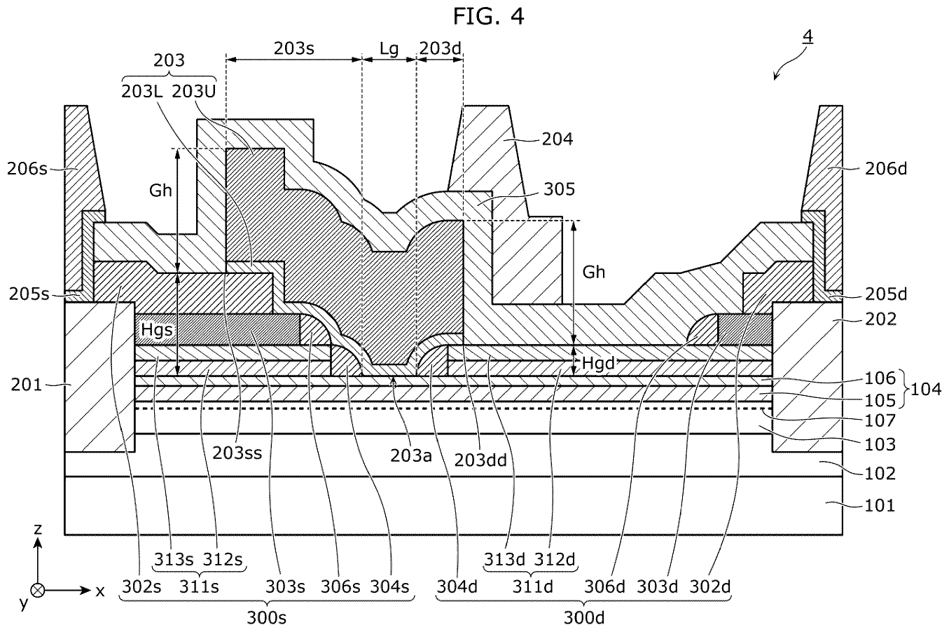

FIG. 4 is a cross-sectional view of semiconductor device 4 according to the present embodiment. As illustrated in FIG. 4, semiconductor device 4 differs from semiconductor device 2 in that source-side insulating layer 300s further includes fifth insulating film 303s and sidewall 306s, and drain-side insulating layer 300d further includes sixth insulating film 303d and sidewall 306d. The drain-side end portion of source-side insulating layer 300s is formed in a three-stage step structure.

Fifth insulating film 303s overlaps with source-side protruding portion 203s in a plan view, and is positioned between first insulating film 311s and second insulating film 302s. More specifically, fifth insulating film 303s contacts and covers first insulating film 311s in the area from the position overlapping with source-side protruding portion 203s in a plan view of substrate 101 to source electrode 201. Fifth insulating film 303s consists of Si₃N₄, for example, but may consist of SiO₂ or SiON.

The end portion of fifth insulating film 303s on the drain electrode 202 side (positive side of the x-axis) is receded toward the source electrode 201 side (negative side of the x-axis) relative to the end portion of first insulating film 311s on drain electrode 202 side. Therefore, a portion of the top surface of first insulating film 311s is not covered by fifth insulating film 303s, and contacts the bottom surface of source-side protruding portion 203s of gate electrode 203.

The top surface of fifth insulating film 303s is covered by second insulating film 302s, except for the portion that contacts the bottom surface of source-side protruding portion 203s. In the present embodiment, second insulating film 302s contacts and covers the top surface of fifth insulating film 303s. The end portion of second insulating film 302s on the gate electrode 203 side is receded toward the source electrode 201 side relative to the end portion of fifth insulating film 303s on gate electrode 203 side.

Sidewall 306s is disposed on the top surface of first insulating film 311s so as to contact the end surface of fifth insulating film 303s. In the example illustrated in FIG. 4, sidewall 306s contacts and covers the top surface of first insulating film 311s up to the end portion on the drain electrode 202 side, and is provided so as to contact sidewall 304s or be integrated therewith, but is not limited thereto. Sidewall 306s need not necessarily cover a portion of the top surface of first insulating film 311s. Sidewall 306s consists of Si₃N₄, for example. Sidewall 306s is formed in the same process as second insulating film 302s and sidewall 304s.

Sixth insulating film 303d is disposed between third insulating film 311d and fourth insulating film 302d. Sixth insulating film 303d does not overlap with drain-side protruding portion 203d of gate electrode 203 in a plan view of substrate 101. Sixth insulating film 303d is in contact with drain electrode 202 and is provided so as to extend toward the gate electrode 203 side. Sixth insulating film 303d consists of Si₃N₄, for example, but may consist of SiO₂ or SiON.

Sixth insulating film 303d can be formed in the same process as fifth insulating film 303s on the source electrode 201 side. Therefore, sixth insulating film 303d has the same thickness and film quality as fifth insulating film 303s. For example, the thickness of each of sixth insulating film 303d and fifth insulating film 303s is greater than or equal to 50 nm and less than or equal to 100 nm, and in one example is 100 nm, but is not limited thereto.

Sidewall 306d is disposed on the top surface of third insulating film 311d so as to contact the end surface of sixth insulating film 303d. Sidewall 306d consists of Si₃N₄, for example. Sidewall 306d is formed in the same process as fourth insulating film 302d and sidewall 304d.

In the present embodiment, at a position overlapping with source-side protruding portion 203s in a plan view, three insulating films, namely first insulating film 311s, fifth insulating film 303s, and second insulating film 302s are formed in a step structure. Accordingly, a three-stage step is formed on the bottom surface of source-side protruding portion 203s. Accordingly, height Hgs of end portion 203ss on the source electrode 201 side of the bottom surface of source-side protruding portion 203s can be made higher. Therefore, gate-source parasitic capacitance Cgs can be further reduced.

In the vicinity of drain electrode 202, three insulating films, namely third insulating film 311d, sixth insulating film 303d, and fourth insulating film 302d are stacked. Accordingly, due to the increase in piezo stress, the carrier concentration of 2 DEG 107 in the vicinity of drain electrode 202 can be increased. Therefore, on-resistance Ron of the transistor can be reduced.

It should be noted that in the present embodiment, similar to Embodiment 2, first insulating film 311s and third insulating film 311d may have a stacked structure of a Si₃N₄ film and a SiO₂ film. Second insulating film 302s and fourth insulating film 302d, or fifth insulating film 303s and sixth insulating film 303d, may have a stacked structure of a Si₃N₄ film and a SiO₂ film. The number of stacked layers of each insulating film may be greater than or equal to three. One of fifth insulating film 303s or sixth insulating film 303d need not necessarily be provided.

### Embodiment 5

Next, Embodiment 5 will be described. In Embodiment 5, the main difference from Embodiment 4 is that the fourth insulating film and the sixth insulating film extend toward the gate electrode side. The description below will focus on the differences from Embodiment 4, and the description of common points will be omitted or simplified.

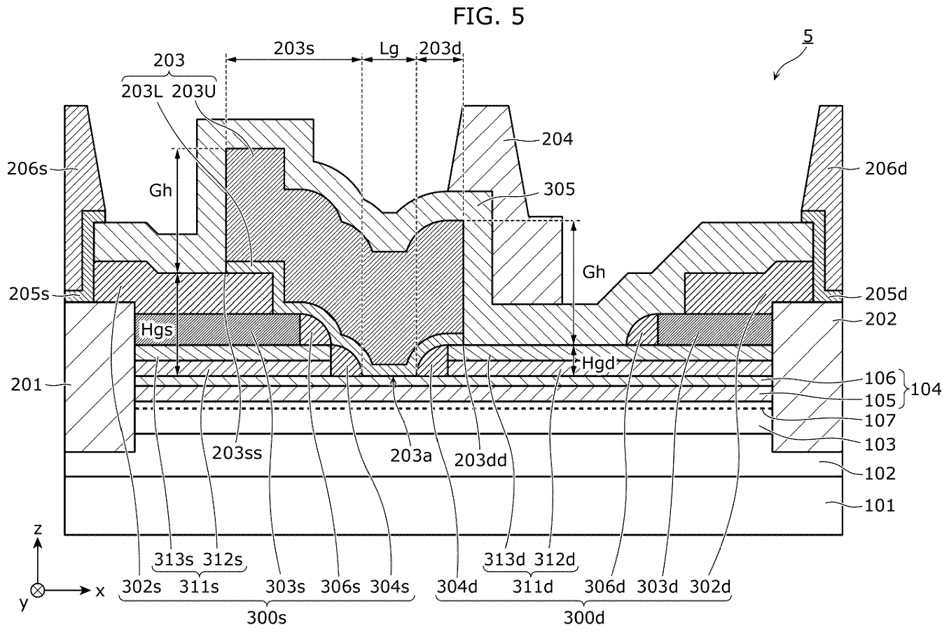

FIG. 5 is a cross-sectional view of semiconductor device 5 according to the present embodiment. As illustrated in FIG. 5, semiconductor device 5 differs from semiconductor device 4 in that fourth insulating film 302d and sixth insulating film 303d extend toward the gate electrode 203 side.

For example, the distance in the x-axis direction between the end portion of sixth insulating film 303d on the gate electrode 203 side and the end portion of drain-side protruding portion 203d of gate electrode 203 is, for example, greater than or equal to ¼ and less than or equal to ¾ of gate-drain distance Lgd, and in one example is ½. The same applies to fourth insulating film 302d.

In the region directly below sixth insulating film 303d and fourth insulating film 302d, the carrier concentration of 2 DEG 107 can be increased due to the effect of increased piezo stress. Therefore, the electrical resistance of 2 DEG 107 in the x-axis direction decreases. Since sixth insulating film 303d and fourth insulating film 302d extend toward the gate electrode 203 side, the region where the electrical resistance of 2 DEG 107 decreases increases, making it possible to reduce on-resistance Ron of the transistor. Semiconductor device 5 is useful when the operating voltage is low.

### Manufacturing Method

Next, a manufacturing method of semiconductor devices 1 to 5 according to the above-described Embodiments 1 to 5 will be described.

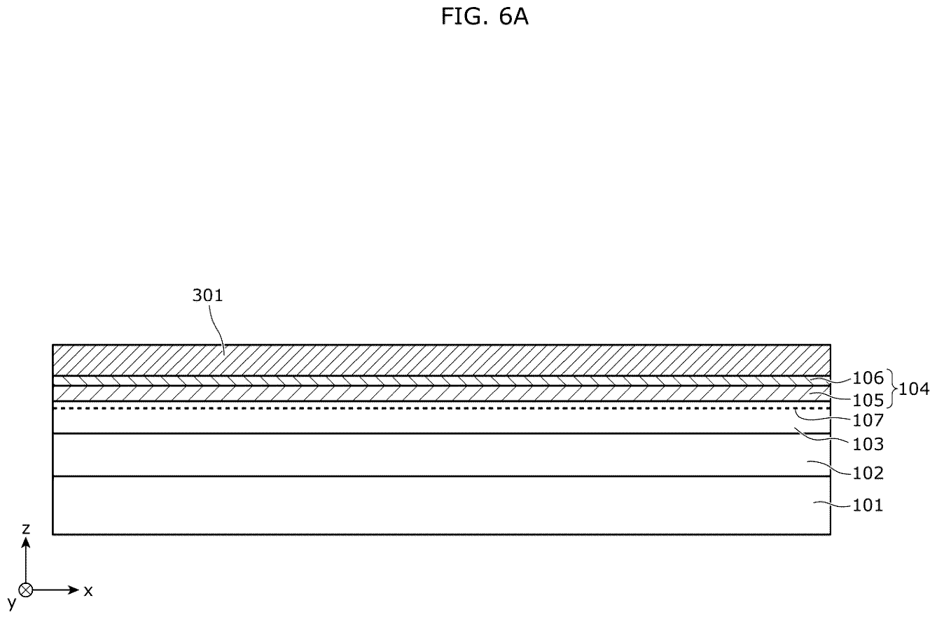

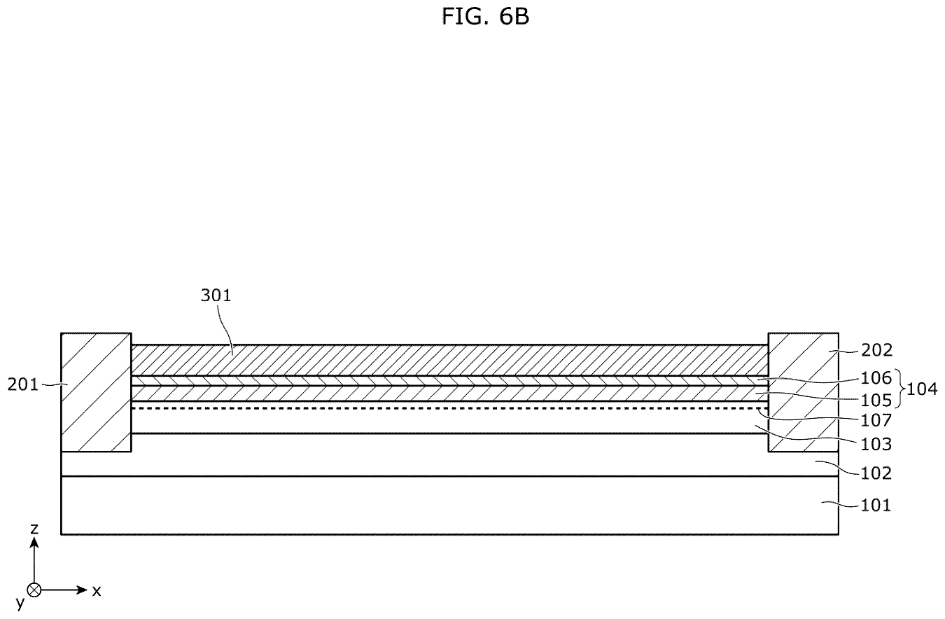

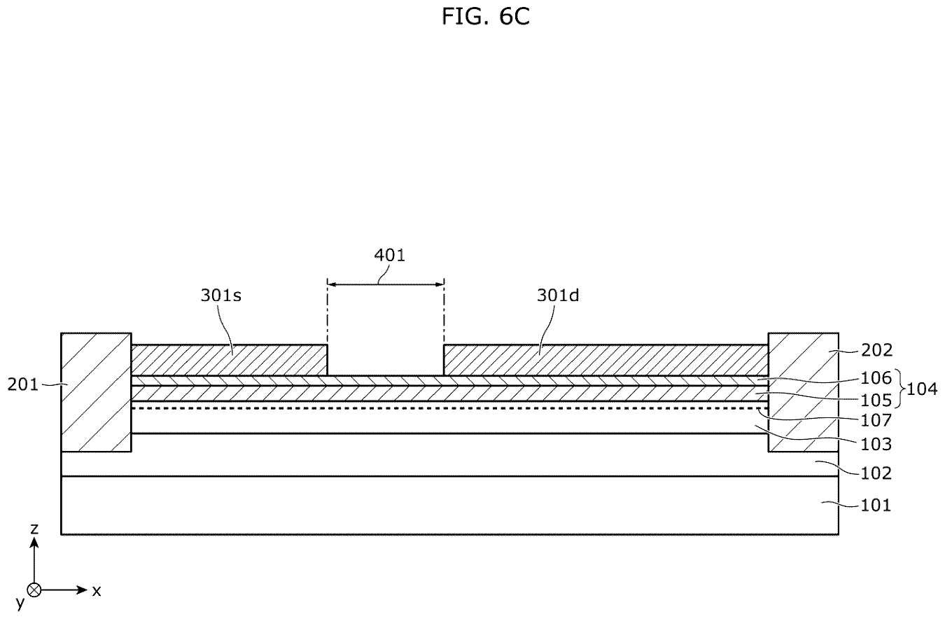

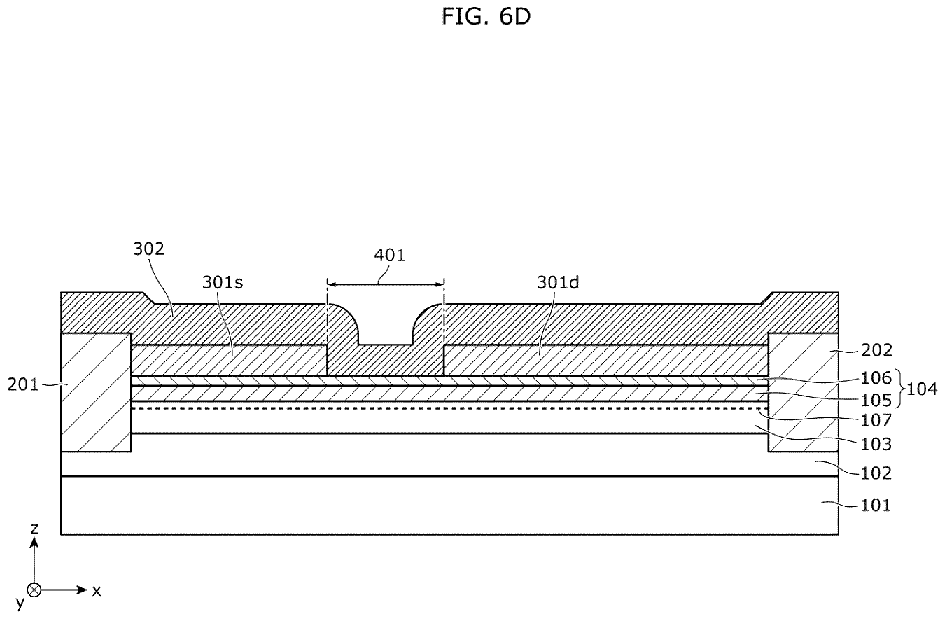

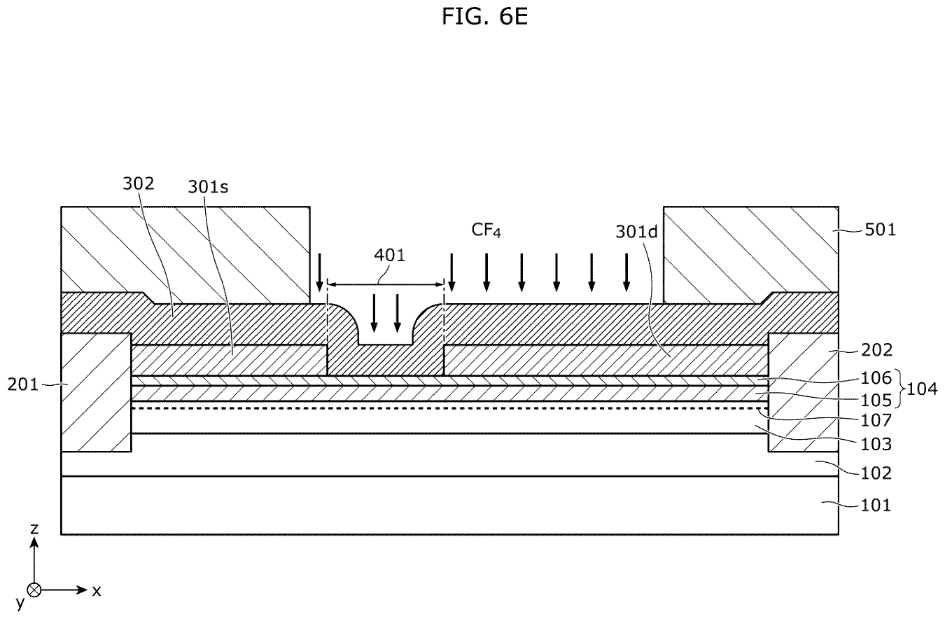

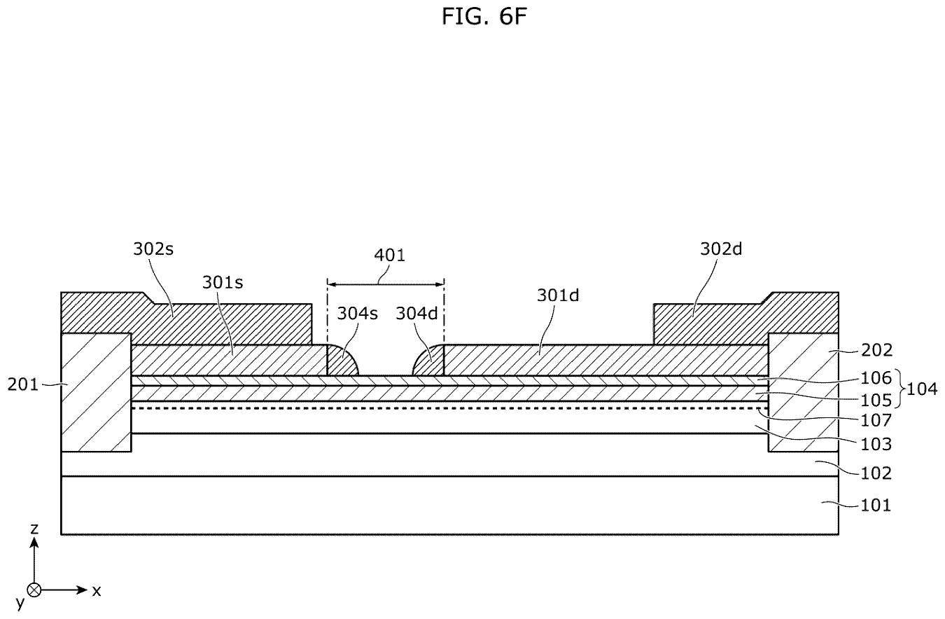

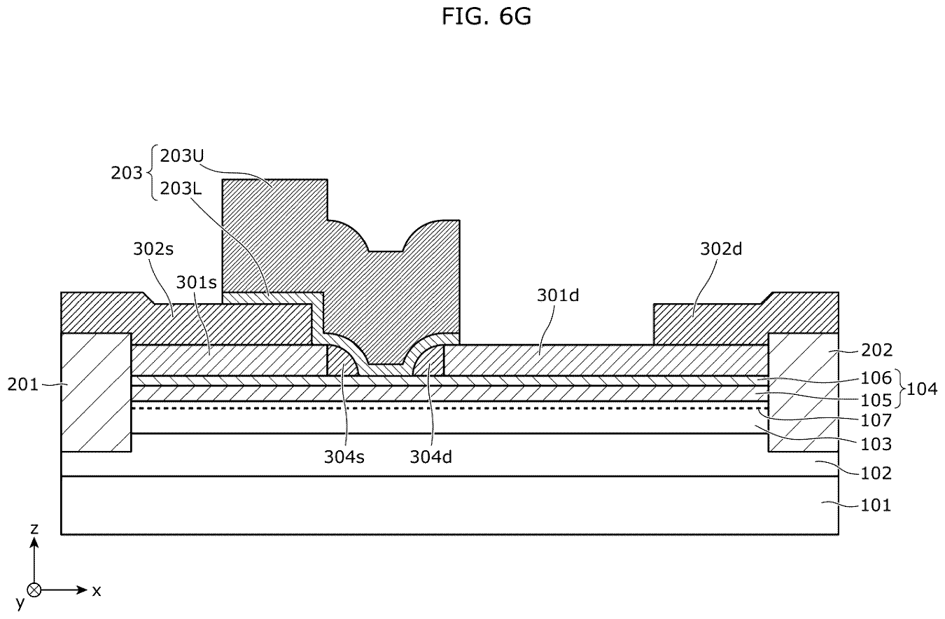

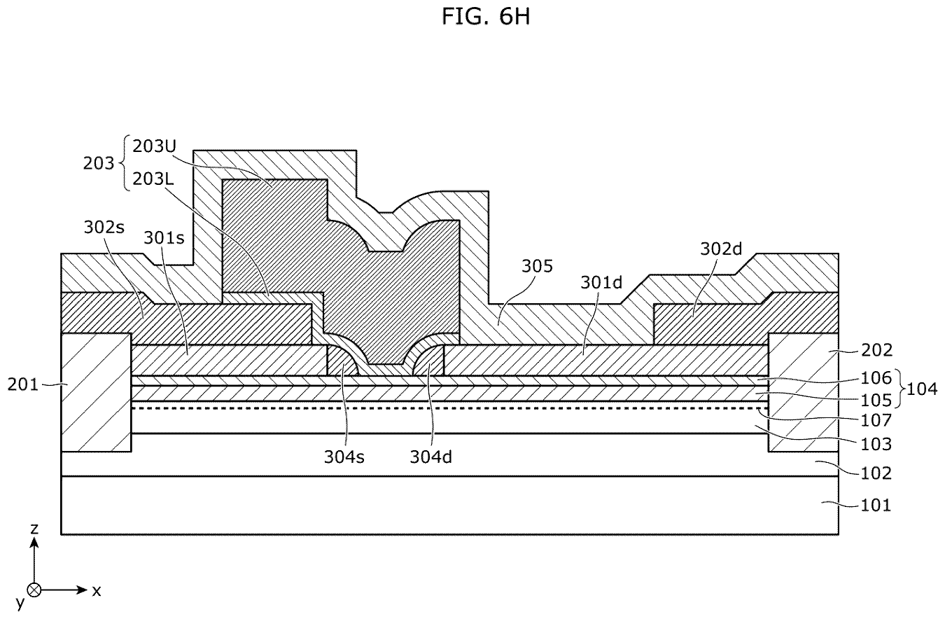

In the following, first, a manufacturing method of semiconductor device 1 according to Embodiment 1 will be described with reference to FIG. 6A to FIG. 6I. FIG. 6A to FIG. 6I are cross-sectional views for illustrating processes of the manufacturing method of semiconductor device 1 according to Embodiment 1.

First, as illustrated in FIG. 6A, a GaN wafer on which a nitride semiconductor has been epitaxially grown is prepared. More specifically, buffer layer 102, channel layer 103, barrier layer 105, and cap layer 106 are sequentially formed on substrate 101. For example, nitride semiconductors such as GaN, AlGaN, etc., are epitaxially grown in sequence. Epitaxial growth is performed, for example, in a growth furnace based on Metal Organic Chemical Vapor Deposition (MOCVD). Buffer layer 102, channel layer 103, barrier layer 105, and cap layer 106 can be formed by adjusting the type and flow rate of the introduced gases.

Furthermore, after cleaning the top surface of cap layer 106 with an acid such as hydrofluoric acid, insulating film 301 consisting of Si₃N₄ is formed. Insulating film 301 is formed, for example, by plasma CVD or Low-Pressure Chemical Vapor Deposition (LPCVD). Alternatively, insulating film 301 may be formed continuously from the formation of cap layer 106, without atmospheric exposure in the MOCVD growth furnace. The Si₃N₄ film crystal-grown after the epitaxial growth of the nitride semiconductor without exposure to the atmosphere is referred to as an in-situ Si₃N₄ film. It should be noted that the Si₃N₄ film formed after atmospheric exposure is referred to as an ex-situ Si₃N₄ film.

Next, although not illustrated in the figures, regions outside the transistor formation region (also called the active region) are deactivated by injecting ions that deactivate the nitride semiconductor, such as boron ions (B⁺). This enables electrical isolation between devices within the GaN wafer.

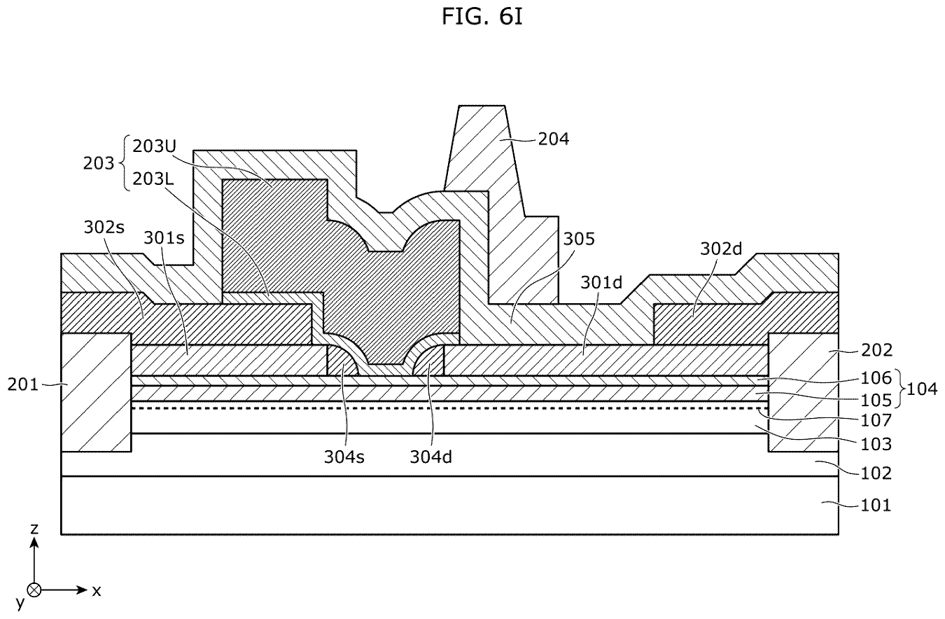

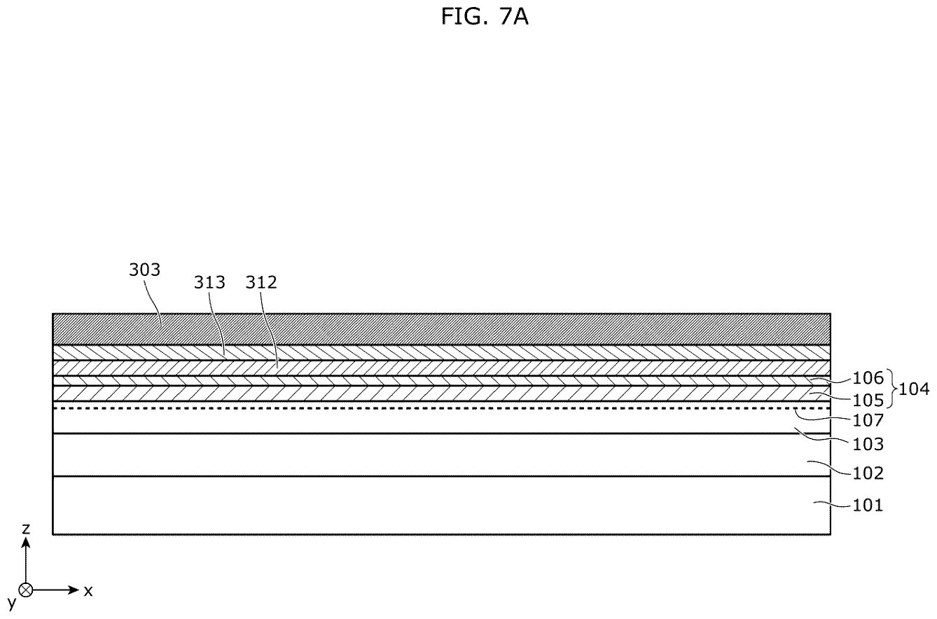

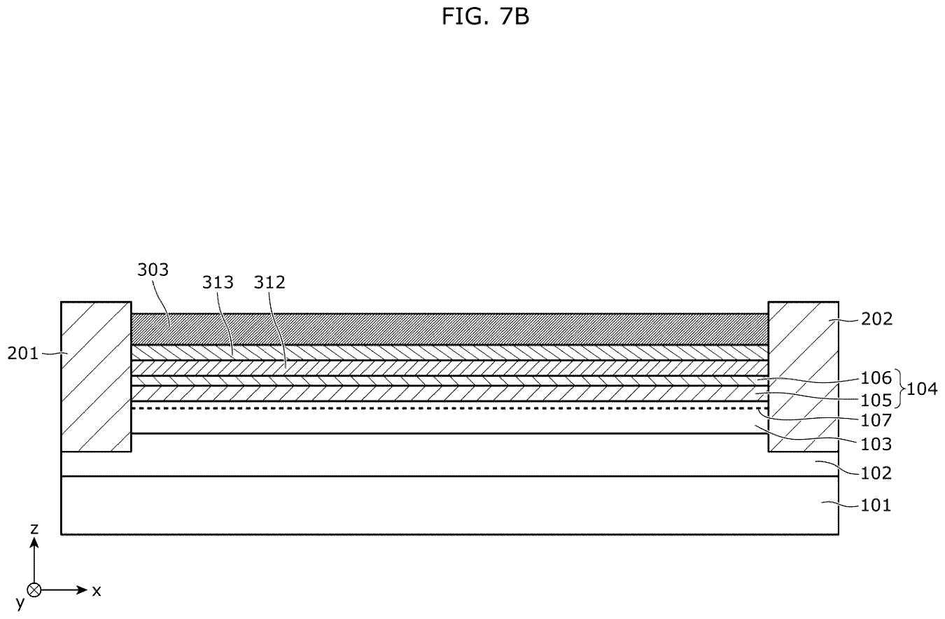

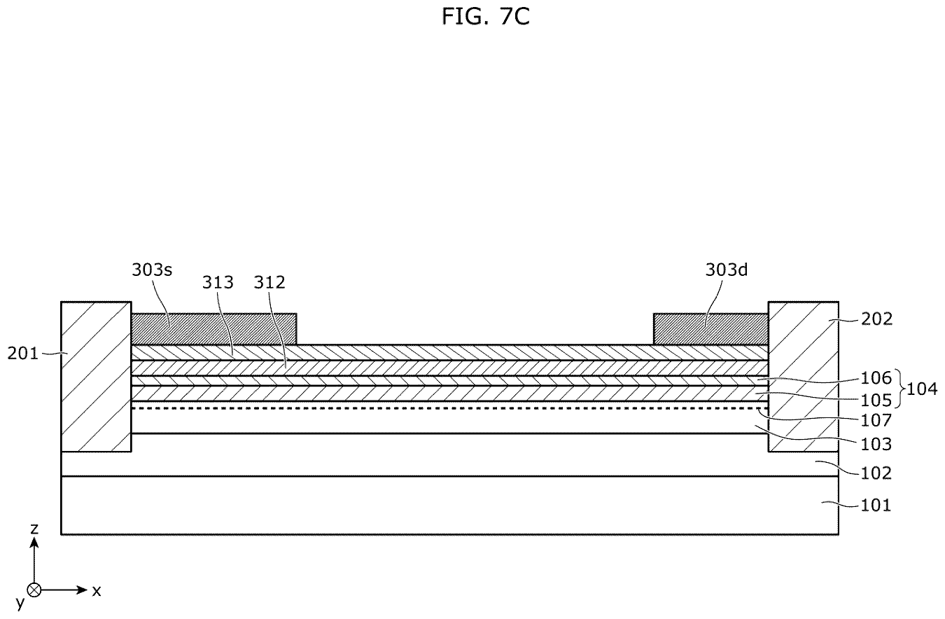

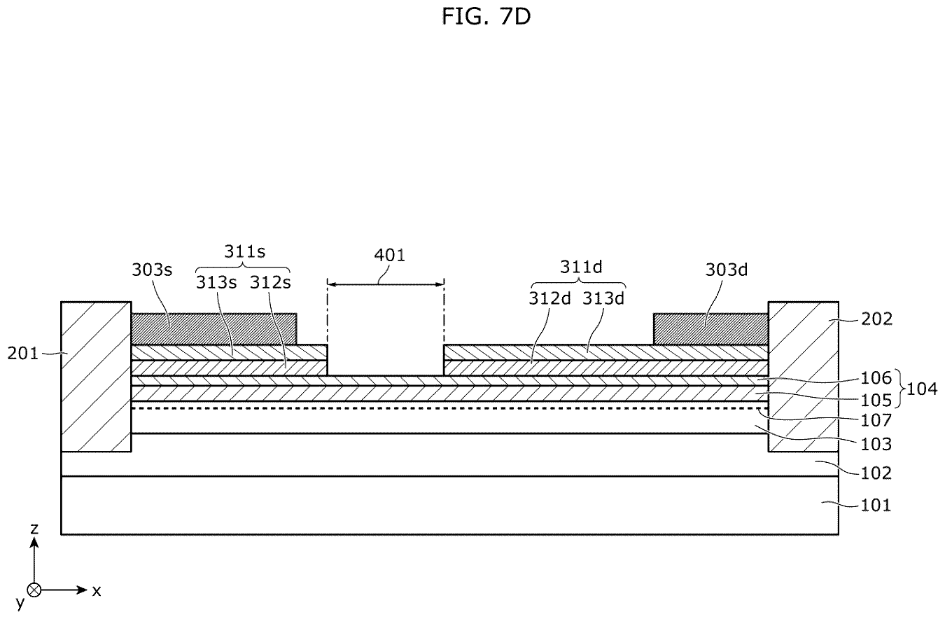

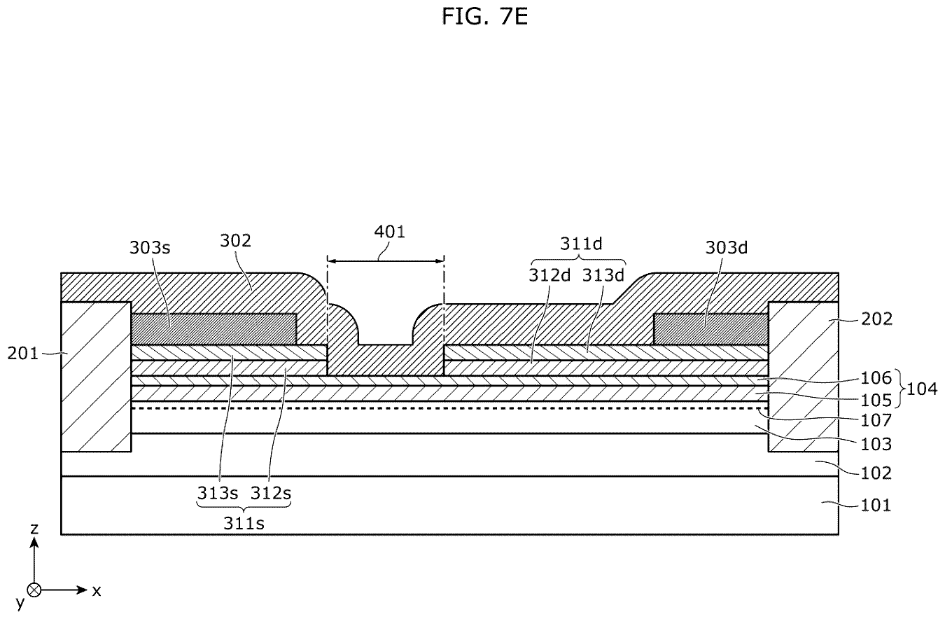

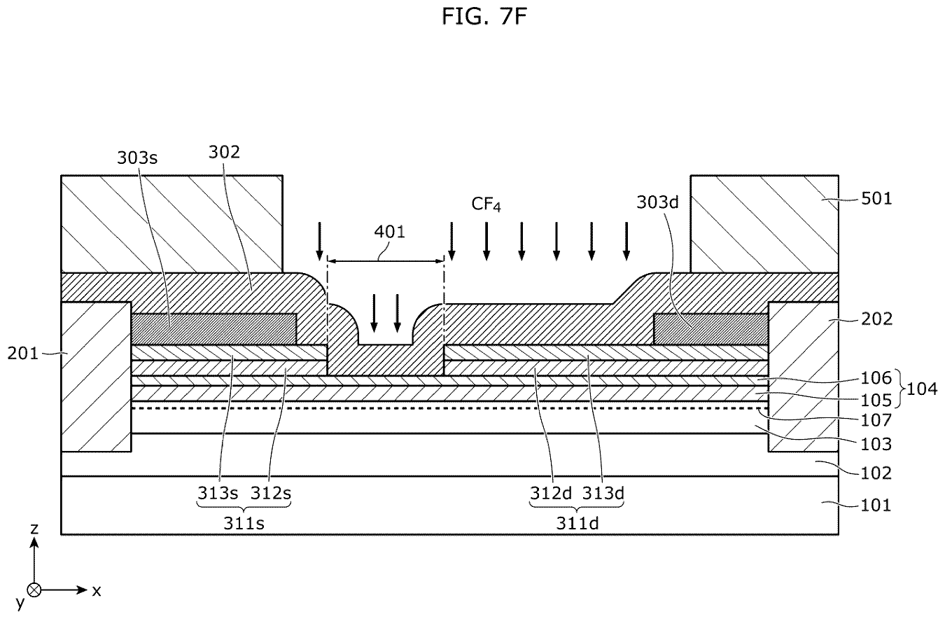

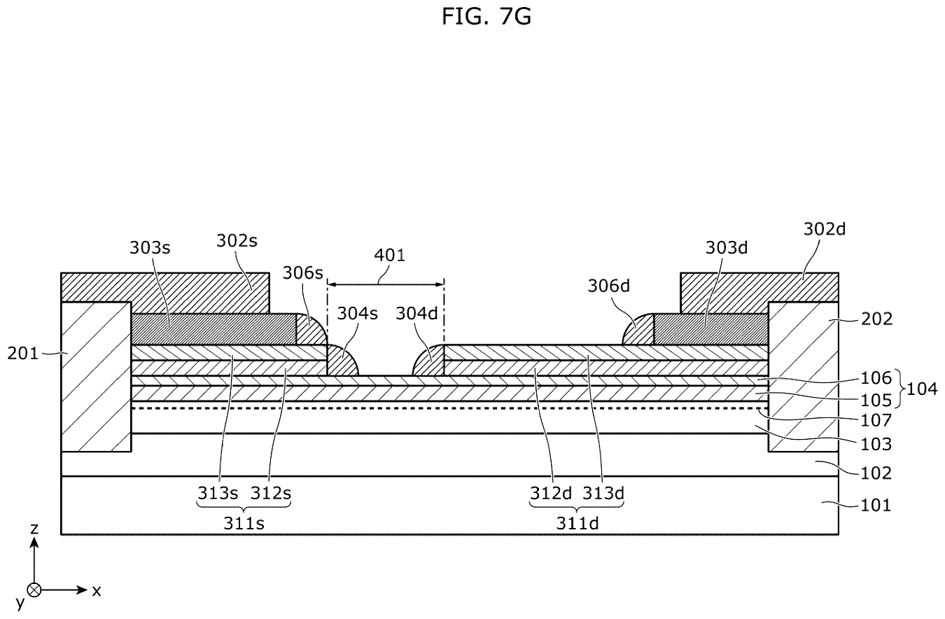

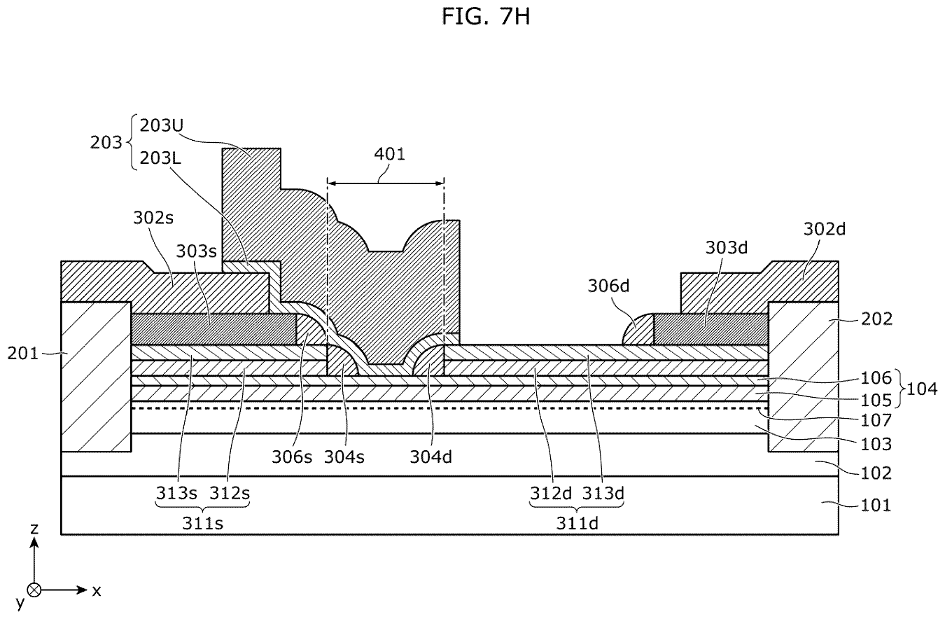

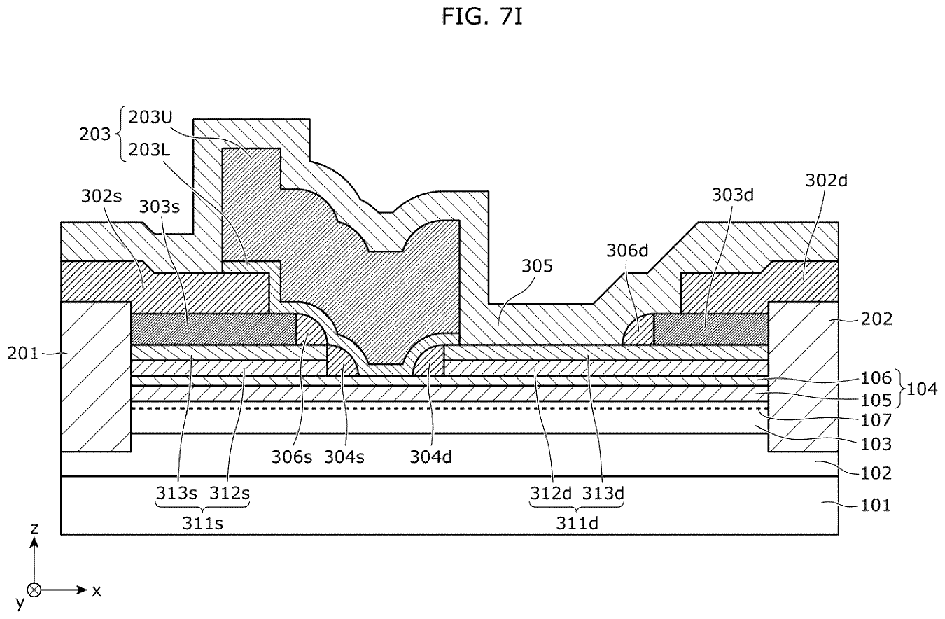

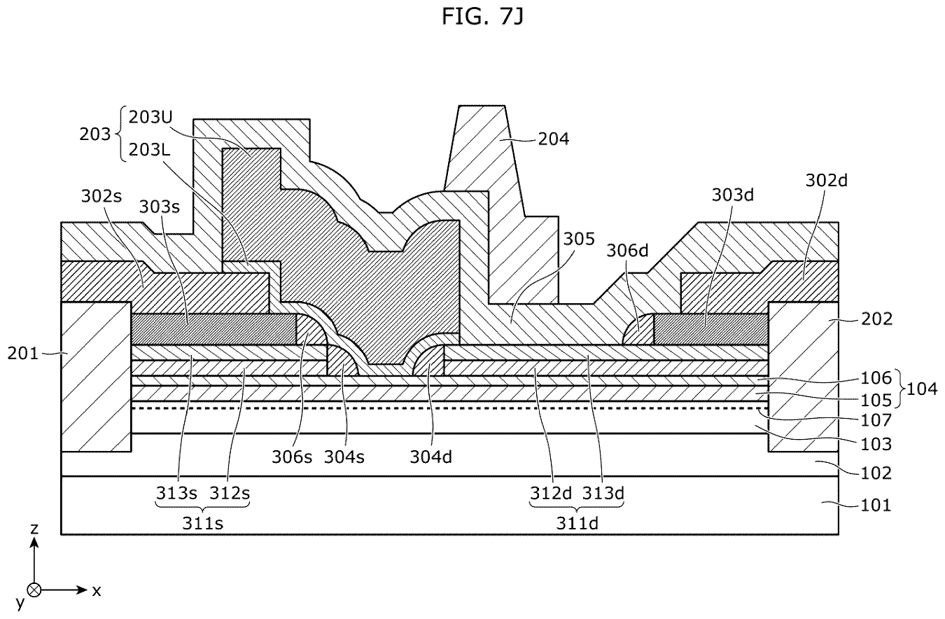

Next, source electrode 201 and drain electrode 202 are formed as illustrated in FIG. 6B. Note that FIG. 6B through FIG. 6I illustrate only one transistor formation region within the GaN wafer. In each figure, the non-illustrated portions to the left of source electrode 201 (negative side of the x-axis) and to the right of drain electrode 202 (positive side of the x-axis) are electrical isolation regions. The same applies to FIG. 7B through FIG. 7J to be described later.

In the process of forming source electrode 201 and drain electrode 202, first, opening portions (contact holes) are formed by removing portions of insulating film 301 through etching. Furthermore, continuously from the formation of the contact holes, a recessed portion is formed by removing cap layer 106, barrier layer 105, and channel layer 103 through etching until 2 DEG 107 is exposed. The etching is performed, for example, by dry etching. After depositing a metal film by sputtering or vapor deposition to cover the inner surface of the formed recessed portion, source electrode 201 and drain electrode 202 are formed by patterning the metal film. Note that the patterning is performed, for example, by etching or lift-off. Subsequently, by alloying the semiconductor and metal at a temperature of approximately 500° C. to 600° C., each of source electrode 201 and drain electrode 202 is made to have ohmic contact with channel layer 103.

Next, as illustrated in FIG. 6C, a gate opening portion is formed in gate region 401 for forming a gate. The length of gate region 401 in the x-axis direction is, for example, 0.39 μm. More specifically, a positive photoresist is applied on insulating film 301, and gate region 401 of the applied photoresist is opened. Dry etching with plasma ions containing CF₄ removes the exposed portion of insulating film 301 in gate region 401. As a result, first insulating film 301s on the source electrode 201 side and third insulating film 301d on the drain electrode 202 side are formed.

Next, as illustrated in FIG. 6D, insulating film 302 consisting of Si₃N₄ is formed on the entire surface, including the opening portion of gate region 401. Insulating film 302 is formed by, for example, plasma CVD, but may be formed by LPCVD. Insulating film 302 is a silicon nitride film that serves as the base for sidewalls 304s and 304d, as well as second insulating film 302s and fourth insulating film 302d. More specifically, insulating film 302 is deposited with the same thickness as each of first insulating film 301s and third insulating film 301d (for example, 100 nm). By matching thicknesses, the height of sidewalls 304s and 304d can be aligned with the height of first insulating film 301s and the height of third insulating film 301d.

Next, as illustrated in FIG. 6E, after forming photoresist 501 having an opening portion of a predetermined shape, anisotropic dry etching is performed using plasma ions mainly containing CF₄ to remove insulating film 302 exposed in the opening portions of photoresist 501. Photoresist 501 has a shape that covers source electrode 201 and drain electrode 202, and does not cover at least gate region 401. The etching amount is the thickness of the deposited insulating film 302, for example, 100 nm.

With gate region 401 as a reference point, the opening portion of photoresist 501 is larger on the drain side than on the source side. Photoresist 501 covers up to an area near gate region 401 on the source side, and covers only the vicinity of drain electrode 202 on the drain side. The shape and size of the opening portion of photoresist 501 are determined according to the shape and size between the end portions of second insulating film 302s and fourth insulating film 302d on the gate electrode 203 side. Photoresist 501 is a positive type, but may be a negative type. After dry etching, photoresist 501 is removed using an organic solvent such as acetone.

As a result of the dry etching, second insulating film 302s and fourth insulating film 302d, as well as sidewall 304s and sidewall 304d are formed, as illustrated in FIG. 6F. As a result of the asymmetry of photoresist 501 with respect to gate region 401, second insulating film 302s on the source side is formed larger than fourth insulating film 302d on the drain side. That is, the distance from second insulating film 302s on the source side to gate region 401 is shorter than the distance from fourth insulating film 302d on the drain side to gate region 401.

Sidewall 304s and sidewall 304d are the remaining portions of insulating film 302 that were not removed along the opening wall in gate region 401. Due to the anisotropic etching process, the top surfaces of sidewalls 304s and 304d replicate the shape of the top surface of insulating film 302. This shape is generally referred to as a sidewall shape. Due to the formation of sidewalls 304s and 304d in gate region 401, the length of the exposed portion of nitride semiconductor layer 104 in gate region 401 (i.e., gate length Lg) is reduced. More specifically, gate length Lg is reduced from 0.39 μm to 0.19 μm.

When the length of gate region 401 is 0.4 μm, it is possible to form the gate opening portion using i-line photolithography, which is a conventional optical exposure technique. However, it is difficult to form the gate opening portion with a length of 0.25 μm or less. Thus, by forming sidewalls 304s and 304d, gate length Lg can be easily reduced.

Next, gate electrode 203 is formed as illustrated in FIG. 6G. More specifically, a first conductive film made of a material that forms a Schottky junction with the nitride semiconductor is formed as gate electrode lower portion 203L, and a second conductive film made of a material having a lower resistivity than the first conductive film is formed as gate electrode upper portion 203U. For example, after continuously forming the first conductive film and the second conductive film over the entire surface by sputtering or the like, a resist mask may be formed and unnecessary portions may be removed by dry etching. Alternatively, gate electrode 203 may be formed by lift-off method. More specifically, after forming a resist film having an opening in a portion corresponding to gate electrode 203, the first conductive film and the second conductive film may be continuously deposited, and the resist film may be removed together with the first conductive film and the second conductive film provided on the resist film.

It should be noted that the thicker the thickness of gate electrode upper portion 203U, the greater the reduction in gate resistance Rg that can be expected. However, due to the skin effect of metal, current flows only through the surface (skin portion) in the case of high frequency. It is therefore not necessarily better for gate electrode upper portion 203U to be thicker. In the case of gate electrode upper portion 203U consisting of Al, a thickness of approximately 450 nm is sufficient to accommodate the frequency bands currently applied. Thickening of gate electrode upper portion 203U may be subject to constraints such as deposition time and etching time, as well as the thickness of the photoresist mask. For example, when depositing Al by sputtering, the greater the thickness, the longer the deposition time and etching time become, which may cause the resist mask for processing to become baked and difficult to remove. When depositing by evaporation lift-off method, poor lift-off characteristics can easily cause shape abnormalities. For this reason, gate electrode upper portion 203U is set to a maximum thickness of approximately 650 nm.

Next, as illustrated in FIG. 6H, insulating layer 305 is formed to protect gate electrode 203. As insulating layer 305, a Si₃N₄ film is formed by, for example, plasma CVD or LPCVD.

Next, source field plate 204 is formed as illustrated in FIG. 6I. Source field plate 204 is formed by depositing a metal film by sputtering and removing by dry etching. Alternatively, source field plate 204 may be formed by vapor deposition lift-off. When Au is used, vapor deposition lift-off is employed because dry etching cannot be performed.

Next, in order to ensure electrical connection with source electrode 201 and drain electrode 202, opening portions are first formed in insulating layer 305 and second insulating film 302s and fourth insulating film 302d. The formation of the opening portions is performed by forming a photoresist having opening portions provided to expose source electrode 201 and drain electrode 202, and then dry etching with plasma ions containing CF₄. Subsequently, barrier metals 205s and 205d and wiring metals 206s and 206d of predetermined shapes are formed to cover the opening portions. Barrier metals 205s and 205d, as well as wiring metals 206s and 206d, are formed by sputtering and dry etching, or by deposition lift-off method.

Through the above processes, semiconductor device 1 illustrated in FIG. 1 can be manufactured.

Semiconductor devices 2 and 3 according to Embodiments 2 and 3 are manufactured by modifying portions of the processes included in the manufacturing method of semiconductor device 1 described above. In the case of semiconductor device 2, in the process described with reference to FIG. 6A, following the formation of insulating film 301 consisting of Si₃N₄, a SiO₂ film may be formed by plasma CVD or the like. In the process of forming source electrode 201 and drain electrode 202, as well as in forming gate region 401, the SiO₂ film and insulating film 301 consisting of Si₃N₄ may be continuously etched.

In the case of semiconductor device 3, in the process described with reference to FIG. 6E, the shape of photoresist 501 may be changed. More specifically, the portion of photoresist 501 that overlaps with drain-side third insulating film 301d in plan view may be enlarged to bring it closer to gate region 401.

Next, a manufacturing method of semiconductor device 5 according to Embodiment 5 will be described with reference to FIG. 7A to FIG. 7J. FIG. 7A to FIG. 7J are cross-sectional views for illustrating processes of the manufacturing method of semiconductor device 5 according to Embodiment 5.

First, as illustrated in FIG. 7A, a GaN wafer on which a nitride semiconductor has been epitaxially grown is prepared. On cap layer 106, which is the uppermost layer of the epitaxial growth, insulating film 312 consisting of Si₃N₄, insulating film 313 consisting of SiO₂, and insulating film 303 consisting of Si₃N₄ are sequentially formed. Insulating film 312 may be an in-situ Si₃N₄ film or may be an ex-situ Si₃N₄ film. Insulating film 313 is formed by, for example, plasma CVD. Insulating film 303 is formed by, for example, LPCVD, but may be formed by atmospheric pressure CVD. For example, the thickness of insulating films 312, 313, and 303 is 50 nm, 50 nm, and 100 nm, respectively, but is not limited thereto.

Next, source electrode 201 and drain electrode 202 are formed as illustrated in FIG. 7B. It should be noted that before the formation of source electrode 201 and drain electrode 202, a process is performed to deactivate regions other than the transistor formation region.

In the process of forming source electrode 201 and drain electrode 202, a portion of each of insulating films 303, 313, and 312 is removed to form contact holes. The formation and patterning of the metal film, as well as processes such as alloying, are the same as in the manufacturing method of semiconductor device 1. Note that when the bottom surface of source-side protruding portion 203s of gate electrode 203 has a three-stage configuration, the distance between gate electrode 203 and source electrode 201 becomes shorter. When gate electrode 203 and source electrode 201 come too close together, the parasitic capacitance with respect to the side surface of source electrode 201 increases. Therefore, the gate-source distance is made longer by, for example, 0.2 μm compared to when the bottom surface of source-side protruding portion 203s has a two-stage configuration.

Next, by patterning insulating film 303 consisting of Si₃N₄, fifth insulating film 303s and sixth insulating film 303d are formed as illustrated in FIG. 7C. More specifically, a portion of insulating film 303 is removed by anisotropic dry etching. The dry etching is performed by, for example, plasma ions of CF₄ gas. CF₄ gas has a difference in etching rate between Si₃N₄ and SiO₂, and has selective removal properties. More specifically, CF₄ gas has a fast etching rate for Si₃N₄, whereas it has a slow etching rate for SiO₂. Therefore, insulating film 313 consisting of SiO₂ functions as an etch stopper layer, so after removing insulating film 303 consisting of Si₃N₄, the progress of etching can be stopped by insulating film 313. Therefore, the shape illustrated in FIG. 7C can be easily formed. Thus, insulating film 313 consisting of SiO₂ is useful for forming gate electrode 203 having a bottom surface with a three-stage configuration. It should be noted that when insulating film 313 consists of Si₃N₄, gate electrode 203 having a bottom surface with a three-stage configuration can be formed by strictly controlling the etching time and thickness.

Next, as illustrated in FIG. 7D, a gate opening portion is formed in gate region 401 for forming a gate. In the formation of the gate opening portion, insulating film 313 consisting of SiO₂ and insulating film 312 consisting of Si₃N₄ are removed. The removal of insulating films 313 and 312 is performed, for example, by dry etching using CF₄ gas. As described above, the etching rate for SiO₂ is slower than the etching rate for Si₃N₄, but since the thickness of insulating film 313 consisting of SiO₂ is at most approximately 50 nm, etching is possible. By forming the gate opening portion, as illustrated in FIG. 7D, Si₃N₄ film 312s and SiO₂ film 313s (first insulating film 311s) on the source electrode 201 side and Si₃N₄ film 312d and SiO₂ film 313d (third insulating film 311d) on the drain electrode 202 side are formed.

Next, as illustrated in FIG. 7E, insulating film 302 consisting of Si₃N₄ is formed on the entire surface, including the opening portion of gate region 401. Insulating film 302 is formed by, for example, plasma CVD, but may be formed by LPCVD. Insulating film 302 is a silicon nitride film that serves as the base for sidewalls 304s, 304d, 306s and 306d, as well as second insulating film 302s and fourth insulating film 302d. More specifically, insulating film 302 is deposited with the same thickness as each of first insulating film 311s and third insulating film 311d (for example, 100 nm). By matching thicknesses, the height of sidewalls 304s and 304d can be aligned with the height of first insulating film 311s and the height of third insulating film 311d. Also, by making the thickness of each of fifth insulating film 303s and sixth insulating film 303d the same as the thickness of insulating film 302, the height of sidewalls 306s and 306d can be aligned with the height of fifth insulating film 303s and the height of sixth insulating film 303d.

Next, as illustrated in FIG. 7F, after forming photoresist 501 having an opening portion of a predetermined shape, anisotropic dry etching is performed using plasma ions mainly containing CF₄ to remove insulating film 302 exposed in the opening portions of photoresist 501. Photoresist 501 has a shape that covers source electrode 201 and drain electrode 202, and does not cover at least gate region 401. The etching amount is the thickness of the deposited insulating film 302, for example, 50 nm.

As a result of the dry etching, second insulating film 302s and fourth insulating film 302d, as well as sidewalls 304s, 304d, 306s, and 306d are formed, as illustrated in FIG. 7G. As a result of the asymmetry of photoresist 501 with respect to gate region 401, second insulating film 302s on the source side is formed larger than fourth insulating film 302d on the drain side. That is, the distance from second insulating film 302s on the source side to gate region 401 is shorter than the distance from fourth insulating film 302d on the drain side to gate region 401.

Next, gate electrode 203 is formed as illustrated in FIG. 7H. The specific formation method is the same as the method described with reference to FIG. 6G. In the example illustrated in FIG. 7H, on the source electrode 201 side relative to gate region 401, three insulating films, namely first insulating film 311s, fifth insulating film 303s, and second insulating film 302s are arranged in a step structure. Therefore, by forming gate electrode 203 to cover the end portions of these three insulating films, a step can be formed on the bottom surface of source-side protruding portion 203s of gate electrode 203.

Next, as illustrated in FIG. 7I, insulating layer 305 is formed to protect gate electrode 203. As insulating layer 305, a Si₃N₄ film is formed by, for example, plasma CVD or LPCVD.

Next, source field plate 204 is formed as illustrated in FIG. 7J. Source field plate 204 is formed by depositing a metal film by sputtering and removing by dry etching. Alternatively, source field plate 204 may be formed by vapor deposition lift-off. When Au is used, vapor deposition lift-off is employed because dry etching cannot be performed.

Next, in order to ensure electrical connection with source electrode 201 and drain electrode 202, opening portions are first formed in insulating layer 305 and second insulating film 302s and fourth insulating film 302d. The formation of the opening portions is performed by forming a photoresist having opening portions provided to expose source electrode 201 and drain electrode 202, and then dry etching with plasma ions containing CF₄. Subsequently, barrier metals 205s and 205d and wiring metals 206s and 206d of predetermined shapes are formed to cover the opening portions. Barrier metals 205s and 205d, as well as wiring metals 206s and 206d, are formed by sputtering and dry etching, or by deposition lift-off method.

Through the above processes, semiconductor device 5 illustrated in FIG. 5 can be manufactured.

Semiconductor device 4 according to Embodiment 4 is manufactured by modifying portions of the processes included in the manufacturing method of semiconductor device 5 described above. In the case of semiconductor device 4, in the process described with reference to FIG. 7C, sixth insulating film 303d remaining on the drain electrode 202 side may be made smaller. In the process described with reference to FIG. 7F, the shape of photoresist 501 may be changed. More specifically, the portion of photoresist 501 that overlaps with drain-side third insulating film 311d in plan view may be enlarged to bring it closer to gate region 401. It should be noted that sixth insulating film 303d and third insulating film 311d may be completely removed.

### Advantageous Effects

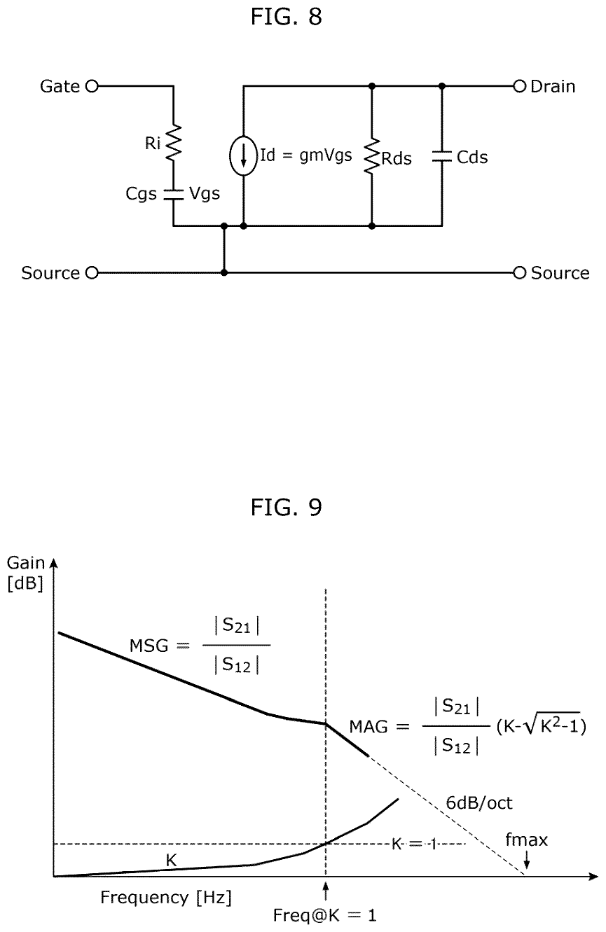

Next, advantageous effects of the semiconductor device according to the present disclosure will be described. In the following, actual data for a prototype of semiconductor device 2 according to Embodiment 2 will be described with reference to FIG. 8 to FIG. 13.

FIG. 8 is a small-signal equivalent circuit diagram of semiconductor device 2 (transistor). By actually measuring the S-parameters of the transistor, each parameter in the equivalent circuit illustrated in FIG. 8 can be extracted. More specifically, it is possible to obtain gate resistance Rg and parasitic capacitances Cgs and Cds, which are targeted for reduction in the present disclosure.

In the equivalent circuit illustrated in FIG. 8, gate resistance Rg is the main component of resistance Ri. In the following, resistance Ri is simply regarded as gate resistance Rg. Note that by separately measuring the intrinsic resistance portion between gate electrode 203 and 2 DEG 107, gate resistance Rg can be calculated more accurately (cold measurement method). However, since a plurality of measurements and calculations are required, Ri is simply regarded as Rg.

FIG. 9 is a diagram for explaining gain improvement. In FIG. 9, the horizontal axis represents frequency, and the vertical axis represents gain.

Indicators for comparing the superiority and inferiority of gain in semiconductor devices include Maximum Stable Gain (MSG) and Maximum Available Gain (MAG). Both MSG and MAG are quantities determined from S-parameters, and therefore are convenient quantities as device indicators.

More specifically, MSG and MAG are expressed by the following Equations (1) and (2), respectively.

$$[ Math . 1 ]$$

$$M S G = \frac{\vert {S}_{21} \vert}{\vert {S}_{12} \vert} \qquad ( 1 )$$

$$M A G = \frac{\vert {S}_{21} \vert}{\vert {S}_{12} \vert} ( K - \sqrt{{K}^{2} - 1} ) \qquad ( 2 )$$

It should be noted that MAG cannot be defined unless K>1, so MSG is used in the range where K≤1. K is called the Kurokawa stability factor and is an indicator of stabilization against oscillation of the transistor. Although K>1 is a desirable condition, there are aspects that can be corrected by the circuit or usage method, and it is possible to use even when K<1. Therefore, MSG is effective when applying a device to an actual circuit.

Since MAG measurement involves measurement at high frequencies, it is limited by the upper limit value of the frequency of the measuring instrument. For frequencies above the measurement limit, extrapolation is performed with a slope of 6 dB/oct. This slope is based on a model in which the gain is inversely proportional to the square of the frequency in the high frequency region.

The minimum gain of 1×, that is, the frequency at 0 dB when MAG is extrapolated, is the maximum oscillation frequency fmax. fmax is required to be sufficiently high relative to the application frequency, for example, three times or more the application frequency. It should be noted that the frequency when Mason's maximum unilateral gain Mu is 0 dB is the original definition of fmax, but it coincides with the maximum oscillation frequency obtained from MAG.

Generally, the higher the switching frequency Freq@K=1 between MSG and MAG, the higher fmax becomes. Therefore, it becomes possible to compare the superiority or inferiority of gain at the switching frequency Freq@K=1.

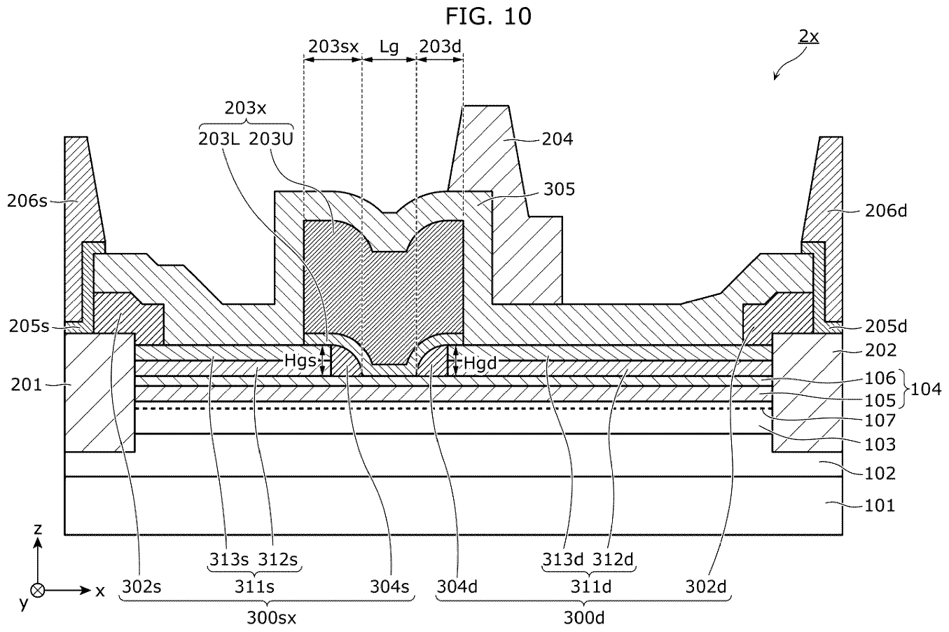

The following describes the comparison results between the example and the comparative example for each of resistance Ri (corresponding to gate resistance Rg), parasitic capacitance Cgs, and switching frequency Freq@K=1. Note that the example is, as described above, a prototype having h the configuration of semiconductor device 2 illustrated in FIG. 2. The comparative example is a prototype having the configuration of semiconductor device 2x illustrated in FIG. 10.

Semiconductor device 2x according to the comparative example differs from semiconductor device 2 in that the cross-sectional shape of gate electrode 203x is different. More specifically, no step is formed on the bottom surface of source-side protruding portion 203sx of gate electrode 203x, and height Hgs of the source-side end portion of the bottom surface of source-side protruding portion 203sx is the same as height Hgd of the drain-side end portion of the bottom surface of drain-side protruding portion 203d. In source-side insulating layer 300sx, sidewall 304s and first insulating film 311s are provided between source-side protruding portion 203sx and nitride semiconductor layer 104, and second insulating film 302s is not provided.

The protrusion length of source-side protruding portion 203sx is approximately 0.2 μm longer than the protrusion length of drain-side protruding portion 203d. To reduce gate resistance Rg, it is desirable to increase the cross-sectional area of gate electrode 203, but extending it toward the drain electrode 202 side would cause problems of decreased gain and efficiency due to increased gate-drain parasitic capacitance Cgd. While extending toward the source electrode 201 side increases gate-source parasitic capacitance Cgs, the reduction in gate resistance Rg ultimately improves the gain characteristics.

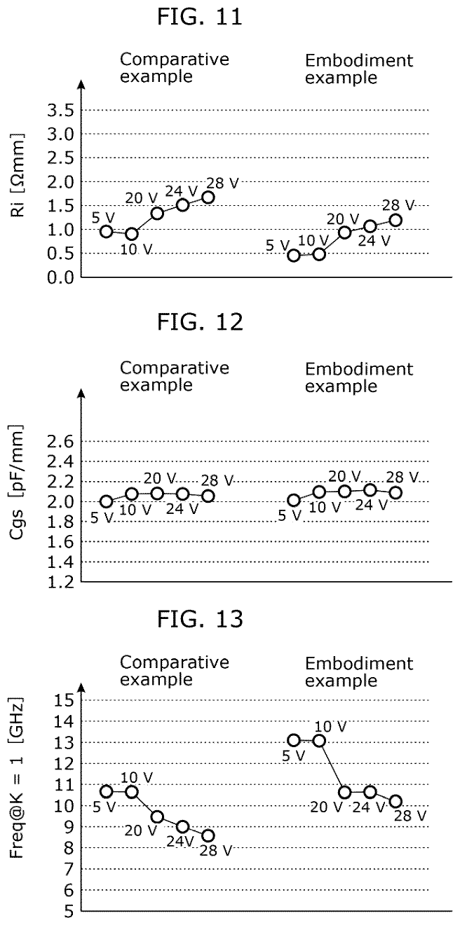

FIG. 11 illustrates the drain voltage dependence of gate resistance Ri (Rg) in comparison between a comparative example and an embodiment example. In FIG. 11, the voltages such as “5V” shown near each plot represent the drain voltage. The same applies to FIG. 12 and FIG. 13 to be described later. The drain voltage corresponds to the electric potential difference between source electrode 201 and drain electrode 202. As illustrated in FIG. 11, when comparing gate resistance Ri at each drain voltage, it is evident that the embodiment example was able to reduce gate resistance Ri compared to the comparative example.

FIG. 12 illustrates the drain voltage dependence of gate-source parasitic capacitance Cgs in comparison between a comparative example and an embodiment example. As illustrated in FIG. 12, it is evident that parasitic capacitance Cgs is approximately the same between the comparative example and the embodiment example. That is, in the embodiment example, although the opposing area between source-side protruding portion 203s of gate electrode 203 and 2 DEG 107 is increased, by providing a step on the bottom surface, it is possible to inhibit an increase in parasitic capacitance Cgs.

FIG. 13 illustrates the drain voltage dependence of switching frequency Freq@K=1 in comparison between a comparative example and an embodiment example. As illustrated in FIG. 13, switching frequency Freq@K=1 is higher in the embodiment example compared to the comparative example at each drain voltage. When the drain voltage is 28V, switching frequency Freq@K=1 is at its lowest, but it still achieves a high value of 10 GHz or more in the double digits. That is, it is evident that stable gain can be obtained even at 10 GHz.

Therefore, according to the structure of gate electrode 203 according to the present disclosure, it is possible to achieve both a reduction in gate resistance and inhibition or reduction of an increase in parasitic capacitances Cgs and Cgd. Therefore, with the semiconductor device according to the present disclosure, gain performance can be improved over a wide frequency range.

While the improvement in gain performance has been described here based on an embodiment example having the structure of semiconductor device 2, gain performance can be similarly improved for semiconductor devices 1 and 3 to 5 as well. Stated differently, in any of semiconductor devices 1 and 3 to 5, since bottom surface 203sa of source-side protruding portion 203s of gate electrode 203 includes a step, it is possible to achieve both a reduction in gate resistance and inhibition or reduction of an increase in parasitic capacitances Cgs and Cgd. Therefore, with semiconductor devices 1, 3 to 5, gain performance can be improved over a wide frequency range.

### Summary

Hereinafter, features of the semiconductor device explained based on the above embodiments will be described.

A semiconductor device according to a first aspect of the present disclosure includes: a substrate; a channel layer disposed above the substrate and including a nitride semiconductor containing gallium; a nitride semiconductor layer disposed above the channel layer and including a barrier layer containing gallium with a bandgap larger than a bandgap of the channel layer; a source electrode and a drain electrode disposed above the substrate and spaced apart from each other; a gate electrode disposed above the barrier layer and between the source electrode and the drain electrode, and spaced apart from each of the source electrode and the drain electrode; a drain-side insulating layer disposed above the nitride semiconductor layer and between the gate electrode and the drain electrode; and a source-side insulating layer disposed above the nitride semiconductor layer and between the gate electrode and the source electrode. The gate electrode includes: a junction portion that forms a Schottky junction with the nitride semiconductor layer; a first protruding portion that protrudes toward the drain electrode from the junction portion; and a second protruding portion that protrudes toward the source electrode from the junction portion. A protrusion length of the second protruding portion is longer than a protrusion length of the first protruding portion. A bottom surface of the second protruding portion includes a step. A height from a top surface of the nitride semiconductor layer to an end portion, of the bottom surface of the second protruding portion, that is closest to the source electrode is greater than a height from the top surface of the nitride semiconductor layer to an end portion, of a bottom surface of the first protruding portion, that is closest to the drain electrode.

With this configuration, by making the gate electrode have a shape that protrudes longer on the source side than on the drain side, it is possible to inhibit an increase in parasitic capacitance Cgd and increase the cross-sectional area of the gate electrode. By increasing the cross-sectional area of the gate electrode, gate resistance Rg can be reduced. By providing a step on the bottom surface of the source-side second protruding portion, it is possible to inhibit an increase in parasitic capacitance Cgs. In this manner, by reducing gate resistance Rg and inhibiting an increase in parasitic capacitances Cgd and Cgs, the gain performance of the transistor can be improved.

A semiconductor device according to a second aspect of the present disclosure is the semiconductor device according to the first aspect, wherein a thickness of the first protruding portion and a thickness of the second protruding portion are constant and equal to each other.

This configuration makes it possible to increase the cross-sectional area of the gate electrode and further reduce gate resistance Rg.

A semiconductor device according to a third aspect of the present disclosure is the semiconductor device according to the first or second aspect, wherein the source-side insulating layer includes: a first insulating film positioned between the second protruding portion and the nitride semiconductor layer; and a second insulating film positioned between the second protruding portion and the first insulating film. An end portion of the second insulating film proximate to the drain electrode is receded toward the source electrode relative to an end portion of the first insulating film proximate to the drain electrode.

With this configuration, a step can be formed in the source-side insulating layer by the stacked structure of the first insulating film and the second insulating film. By forming the gate electrode to cover the step in the source-side insulating layer, a step can be formed with high precision on the bottom surface of the source-side second protruding portion of the gate electrode.

A semiconductor device according to a fourth aspect of the present disclosure is the semiconductor device according to the third aspect, wherein a thickness of the second insulating film is greater than a thickness of the first insulating film.

With this configuration, by making the second insulating film thicker, parasitic capacitance Cgs can be further reduced.

A semiconductor device according to a fifth aspect of the present disclosure is the semiconductor device according to the third or fourth aspect, wherein the second insulating film includes a silicon oxide film.

With this configuration, by utilizing SiO₂ having a low dielectric constant, parasitic capacitance Cgs can be further reduced.

A semiconductor device according to a sixth aspect of the present disclosure is the semiconductor device according to any one of the third to fifth aspects, wherein the first insulating film includes: a silicon nitride film that contacts and covers the nitride semiconductor layer; and a silicon oxide film disposed above the silicon nitride film.

With this configuration, by utilizing SiO₂ having a low dielectric constant, parasitic capacitance Cgs can be further reduced.

A semiconductor device according to a seventh aspect of the present disclosure is the semiconductor device according to any one of the third to sixth aspects, wherein the drain-side insulating layer includes: a third insulating film that contacts and covers the nitride semiconductor layer in an area from a position overlapping with the first protruding portion in a plan view of the substrate to the drain electrode; and a fourth insulating film disposed above the third insulating film. The fourth insulating film does not overlap with the first protruding portion in the plan view of the substrate.

With this configuration, by the drain-side insulating layer having a stacked structure, piezo stress and carrier concentration increases in the direction directly below the stacked portion. Therefore, on-resistance Ron can be reduced.

A semiconductor device according to an eighth aspect of the present disclosure is the semiconductor device according to the seventh aspect, wherein the drain-side insulating layer further includes a sixth insulating film disposed between the third insulating film and the fourth insulating film. The sixth insulating film does not overlap with the first protruding portion in the plan view of the substrate.

Therefore, the reduction effect of on-resistance Ron can be further improved.

A semiconductor device according to a ninth aspect of the present disclosure is the semiconductor device according to the seventh or eighth aspect, wherein the third insulating film includes: a silicon nitride film that contacts and covers the nitride semiconductor layer; and a silicon oxide film disposed above the silicon nitride film.

With this configuration, by utilizing SiO₂ having a low dielectric constant, parasitic capacitance Cgd can be further reduced.

A semiconductor device according to a tenth aspect of the present disclosure is the semiconductor device according to any one of the third to ninth aspects, wherein the source-side insulating layer further includes a fifth insulating film that overlaps with the second protruding portion in a plan view of the substrate and is positioned between the first insulating film and the second insulating film. An end portion of the fifth insulating film proximate to the drain electrode is receded toward the source electrode relative to the end portion of the first insulating film proximate to the drain electrode. The end portion of the second insulating film proximate to the drain electrode is receded toward the source electrode relative to the end portion of the fifth insulating film proximate to the drain electrode.

With this configuration, by increasing the number of stacked insulating films included in the source-side insulating layer, the number of steps on the bottom surface of the source-side second protruding portion of the gate electrode can be increased. Therefore, the reduction effect of parasitic capacitance Cgs can be further improved.

### Other Embodiments

Although the semiconductor device according to one or more aspects has been described above based on the embodiments, the present disclosure is not limited to the above-described embodiments. Various modifications to the present embodiment that may be conceived by those skilled in the art, as well as embodiments resulting from combinations of elements from different embodiments, are intended to be included within the scope of the present disclosure as long as these do not depart from the essence of the present disclosure.

For example, drain-side insulating layer 300d need not necessarily be provided in a portion between drain electrode 202 and gate electrode 203. More specifically, drain-side insulating layer 300d only needs to be provided at least in the region that overlaps with drain-side protruding portion 203d in plan view. Drain-side insulating layer 300d need not be disposed in the area from end portion 203dd on the drain electrode 202 side of drain-side protruding portion 203d to drain electrode 202 in plan view.

Also, source-side insulating layer 300s need not necessarily be provided in a portion between source electrode 201 and gate electrode 203. More specifically, source-side insulating layer 300s only needs to be provided at least in the region that overlaps with source-side protruding portion 203s in plan view. Source-side insulating layer 300s need not be disposed in the area from end portion 203ss on the source electrode 201 side of source-side protruding portion 203s to source electrode 201 in plan view.

First insulating film 301s and third insulating film 301d may have a stacked structure of Si₃N₄ films with different film qualities. Si₃N₄ films 312s and 312d may similarly have a stacked structure of Si₃N₄ films with different film qualities. The stacked structure includes, for example, an in-situ Si₃N₄ film that contacts and covers nitride semiconductor layer 104, and an ex-situ Si₃N₄ film provided above the in-situ Si₃N₄ film.

The in-situ Si₃N₄ film is a film consisting of Si₃N₄ that is grown continuously in a growth furnace for epitaxial growth of nitride semiconductors, without exposure to the atmosphere. The ex-situ Si₃N₄ film is a film consisting of Si₃N₄ that is formed after formation of the in-situ Si₃N₄ film, after exposure to the atmosphere. The ex-situ Si₃N₄ film is formed by, for example, LPCVD or atmospheric pressure CVD.

Due to differences in manufacturing methods, the in-situ Si₃N₄ film and the ex-situ Si₃N₄ film have mutually different film qualities. Specifically, the in-situ Si₃N₄ film is a denser film than the ex-situ Si₃N₄ film. For example, the film density of the in-situ Si₃N₄ film is greater than the film density of the ex-situ Si₃N₄ film.

Also, the in-situ Si₃N₄ film and the ex-situ Si₃N₄ film differ in at least one of halogen concentration or interface oxygen concentration. For example, at least one of the following is satisfied: (a) the halogen concentration of the in-situ Si₃N₄ film is lower than the halogen concentration of the ex-situ Si₃N₄ film; or (b) the interface oxygen concentration between the in-situ Si₃N₄ film and nitride semiconductor layer 104 is lower than the interface oxygen concentration between the in-situ Si₃N₄ film and the ex-situ Si₃N₄ film. More specifically, at least one of the following is satisfied: (c) the halogen concentration of the in-situ Si₃N₄ film is less than 1×10¹⁸ atom/cm³, and the halogen concentration of the ex-situ Si₃N₄ film is greater than 1×10¹⁸ atom/cm³; or (d) the interface oxygen concentration between the in-situ Si₃N₄ film and nitride semiconductor layer 104 is less than 1×10²⁰ atom/cm³, and the interface oxygen concentration between the in-situ Si₃N₄ film and the ex-situ Si₃N₄ film is greater than 1×10²⁰ atom/cm³.

The thickness of the in-situ Si₃N₄ film is, for example, greater than or equal to 15 nm, but is not limited thereto. The thickness of the in-situ Si₃N₄ film may be greater than or equal to 20 nm. Also, the thickness of the in-situ Si₃N₄ film is less than or equal to 30 nm, but may be less than or equal to 25 nm.

The thickness of the ex-situ Si₃N₄ film is, for example, greater than or equal to 30 nm and less than or equal to 60 nm. Also, for example, the thickness of the ex-situ Si₃N₄ film is greater than or equal to the thickness of the in-situ Si₃N₄ film.

Since drain-side insulating layer 300d and/or source-side insulating layer 300s have a stacked structure of an in-situ Si₃N₄ film and an ex-situ Si₃N₄ film provided above the in-situ Si₃N₄ film, it is possible to effectively utilize the high piezo stress of the in-situ Si₃N₄ film while also effectively utilizing the wafer bow inhibition effect of the ex-situ Si₃N₄ film. It is possible to inhibit fixed charges from remaining by utilizing electron hopping in the lateral direction of the ex-situ Si₃N₄ film, thereby inhibiting current collapse. Therefore, with the semiconductor device according to the present disclosure, it is possible to achieve a semiconductor device having both high drive current characteristics and low wafer bow characteristics.

Although each of source electrode 201 and drain electrode 202 is formed to be embedded in barrier layer 105 and channel layer 103, the present disclosure is not limited to this. Source electrode 201 and drain electrode 202 may be provided on the top surface of barrier layer 105 or cap layer 106. That is, source electrode 201 and drain electrode 202 need not necessarily be in contact with 2 DEG 107.

In addition, various changes, substitutions, additions, omissions, and so on, can be carried out in the above-described respective embodiments within the scope of the claims or their equivalents.

### INDUSTRIAL APPLICABILITY

The present disclosure is applicable in, for example, power amplifiers for high-output or high-frequency applications, wireless communication base stations or terminal devices in which such power amplifiers are used, or wireless power supply devices that transmit power using microwaves.

1. A semiconductor device comprising:
a substrate;
a channel layer disposed above the substrate and including a nitride semiconductor containing gallium;
a nitride semiconductor layer disposed above the channel layer and including a barrier layer containing gallium with a bandgap larger than a bandgap of the channel layer;
a source electrode and a drain electrode disposed above the substrate and spaced apart from each other;
a gate electrode disposed above the barrier layer and between the source electrode and the drain electrode, and spaced apart from each of the source electrode and the drain electrode;
a drain-side insulating layer disposed above the nitride semiconductor layer and between the gate electrode and the drain electrode; and
a source-side insulating layer disposed above the nitride semiconductor layer and between the gate electrode and the source electrode, wherein
the gate electrode includes:
a junction portion that forms a Schottky junction with the nitride semiconductor layer;
a first protruding portion that protrudes toward the drain electrode from the junction portion; and
a second protruding portion that protrudes toward the source electrode from the junction portion,
a protrusion length of the second protruding portion is longer than a protrusion length of the first protruding portion,
a bottom surface of the second protruding portion includes a step, and
a height from a top surface of the nitride semiconductor layer to an end portion, of the bottom surface of the second protruding portion, that is closest to the source electrode is greater than a height from the top surface of the nitride semiconductor layer to an end portion, of a bottom surface of the first protruding portion, that is closest to the drain electrode.

2. The semiconductor device according to claim 1, wherein
a thickness of the first protruding portion and a thickness of the second protruding portion are constant and equal to each other.

3. The semiconductor device according to claim 1, wherein
the source-side insulating layer includes:
a first insulating film positioned between the second protruding portion and the nitride semiconductor layer; and
a second insulating film positioned between the second protruding portion and the first insulating film, and
an end portion of the second insulating film proximate to the drain electrode is receded toward the source electrode relative to an end portion of the first insulating film proximate to the drain electrode.

4. The semiconductor device according to claim 3, wherein
a thickness of the second insulating film is greater than a thickness of the first insulating film.

5. The semiconductor device according to claim 3, wherein
the second insulating film includes a silicon oxide film.

6. The semiconductor device according to claim 3, wherein
the first insulating film includes:
a silicon nitride film that contacts and covers the nitride semiconductor layer; and
a silicon oxide film disposed above the silicon nitride film.

7. The semiconductor device according to claim 3, wherein
the drain-side insulating layer includes:
a third insulating film that contacts and covers the nitride semiconductor layer in an area from a position overlapping with the first protruding portion in a plan view of the substrate to the drain electrode; and
a fourth insulating film disposed above the third insulating film, and
the fourth insulating film does not overlap with the first protruding portion in the plan view of the substrate.

8. The semiconductor device according to claim 7, wherein
the drain-side insulating layer further includes a sixth insulating film provided between the third insulating film and the fourth insulating film, and
the sixth insulating film does not overlap with the first protruding portion in the plan view of the substrate.

9. The semiconductor device according to claim 7, wherein
the third insulating film includes:
a silicon nitride film that contacts and covers the nitride semiconductor layer; and
a silicon oxide film disposed above the silicon nitride film.

10. The semiconductor device according to claim 3, wherein
the source-side insulating layer further includes a fifth insulating film that overlaps with the second protruding portion in a plan view of the substrate and is positioned between the first insulating film and the second insulating film,
an end portion of the fifth insulating film proximate to the drain electrode is receded toward the source electrode relative to the end portion of the first insulating film proximate to the drain electrode, and
the end portion of the second insulating film proximate to the drain electrode is receded toward the source electrode relative to the end portion of the fifth insulating film proximate to the drain electrode.
